(19) United States
(12) Patent Application Publication
(10) Pub. No.: US 2024/0365666 A1
(43) Pub. Date: Oct. 31, 2024

(54) METHOD FOR FABRICATING ORGANIC LIGHT EMITTING DIODE

(71) Applicant: SFC CO., LTD., Cheongju-si (KR)

(72) Inventors: Jin-Hwi Cho, Cheongju-si (KR); So Young Shim, Cheongju-si (KR); Taejung Yu, Cheongju-si (KR); Sung-Hoon Joo, Cheongju-si (KR)

(21) Appl. No.: 18/630,974

(22) Filed: Apr. 9, 2024

(30) Foreign Application Priority Data
Apr. 26, 2023 (KR) 10-2023-0054864
Feb. 7, 2024 (KR) 10-2024-0019047

(51) Int. Cl. H10K 85/60; H10K 50/12; H10K 71/10

(52) U.S. Cl. CPC H10K 85/658; H10K 50/12; H10K 71/10

(57) ABSTRACT

Disclosed herein is a method for fabricating an organic light-emitting diode. In the method for fabricating an organic light-emitting diode, an organic compound with a substituent in a specific structure is used as a deposition material for an organic layer, whereby the deposition temperature can be reduced, with the consequent minimization of thermal damage to the organic light-emitting diode.

### CROSS-REFERENCE TO RELATED APPLICATIONS

This application claims the priority of the Korean Patent Applications NO 10-2023-0054864, filed on Apr. 26, 2023, and NO 10-2024-0019047, filed on Feb. 7, 2024, in the Korean Intellectual Property Office. The entire disclosures of all these applications are hereby incorporated by reference.

### BACKGROUND OF THE INVENTION

### 1. Field of the Invention

The present disclosure relates to a method for fabricating an organic light-emitting diode. More specifically, the present disclosure relates to a method for fabricating an organic light-emitting diode, wherein an organic compound with a substituent in a specific structure is used as a deposition material for an organic layer, whereby the deposition temperature can be reduced, with the consequent minimization of thermal damage to the organic light-emitting diode.

### 2. Description of the Related Art

Organic light-emitting diodes (OLEDs), based on self-luminescence, are used to create digital displays with the advantage of having a wide viewing angle and being able to be made thinner and lighter than liquid crystal displays. In addition, an OLED display exhibits a very fast response time. Accordingly, OLEDs find applications in the full color display field or the illumination field.

In general, the term “organic light-emitting phenomenon” refers to a phenomenon in which electrical energy is converted to light energy by means of an organic material. An organic light-emitting diode using the organic light-emitting phenomenon has a structure usually including an anode, a cathode, and an organic material layer interposed therebetween. In this regard, the organic material layer may have, for the most part, a multilayer structure consisting of different materials, for example, a hole injection layer, a hole transport layer, a light-emitting layer, an electron transport layer, and an electron injection layer in order to enhance the efficiency and stability of the organic light-emitting diode. In the organic light-emitting diode having such a structure, application of a voltage between the two electrodes injects a hole from the anode and an electron from the cathode to the organic layer. In the luminescent zone, the hole and the electron recombine to produce an exciton. When the exciton returns to the ground state from the excited state, the molecule of the organic layer emits light. Such an organic light-emitting diode is known to have characteristics such as self-luminescence, high luminance, high efficiency, low driving voltage, a wide viewing angle, high contrast, and high-speed response.

Materials used as organic layers in OLEDs may be divided according to functions into luminescent materials and charge transport materials, for example, a hole injection material, a hole transport material, an electron transport material, and an electron injection material. As necessary, an electron blocking layer or a hole blocking layer may be added.

As for the luminescent materials, there are two main families of OLED: those based on small molecules and those employing polymers. The light-emitting mechanism forms the basis of classification of luminescent materials as fluorescent and phosphorescent materials, which use excitons in singlet and triplet states, respectively.

When a single material is employed as the luminescent material, intermolecular actions cause the maximum luminescence wavelength to shift toward a longer wavelength, resulting in a reduction in color purity and luminous efficiency due to light attenuation. In this regard, a host-dopant system may be used as a luminescent material so as to increase the color purity and the luminous efficiency through energy transfer.

This is based on the principle whereby, when a dopant which is smaller in energy band gap than a host forming a light-emitting layer is added in a small amount to the light-emitting layer, excitons are generated from the light-emitting layer and transported to the dopant, emitting light at high efficiency. Here, light with desired wavelengths can be obtained depending on the kind of the dopant because the wavelength of the host moves to the wavelength range of the dopant.

Meanwhile, studies have been made to use boron compounds as dopant compounds. With regard to related art pertaining to the use of boron compounds, reference may be made to Korean Patent No. 10-2016-0119683 A (Oct. 14, 2016), which discloses an organic light-emitting diode employing a novel polycyclic aromatic compound in which multiple aromatic rings are connected via boron and oxygen atoms. In addition, International Patent No. WO 2017/188111 (Nov. 2, 2017) disclosed an organic light-emitting diode in which a compound structured to connect multiple polycondensed aromatic rings via boron and nitrogen atoms is used as a dopant in a light-emitting layer while an anthracene derivative is used as a host.

Deposition processes for organic layers within an organic light-emitting diode are processes to form various layers that make up the pixels of the self-luminescence organic light-emitting devices. For instance, the deposition processes are responsible for forming organic layers including light-emitting layer, hole injection layer, hole transport layer, electron transport layer, electron injection layer, and the like.

Such a deposition process is adapted for depositing a thin film by heating a target material in a vacuum or at a low pressure. In the deposition process, however, materials with high deposition temperatures have a higher possibility of deteriorating the performance of the organic light-emitting diode due to thermal decomposition or decomposed components being deposited on the substrate in the crucible before or during the sublimation process.

Therefore, lowering the deposition temperature of the compounds used in the deposition process for fabricating organic light-emitting devices is a very important issue in the fabricating process. That is, it is crucial to develop materials that satisfy efficiency and longevity conditions while being deposited at low temperatures without decomposing during the deposition process.

However, despite the manufacture of various forms of compounds for use in the light-emitting layer of organic light-emitting devices, including conventional technology, concerns about thermal decomposition are growing, and the range of material choices is gradually narrowing due to the continuously increasing deposition process temperatures driven by the need for large-scale production and high-speed deposition to enhance the productivity of devices such as TVs. Thus, efforts to improve this situation are required.

### SUMMARY OF THE INVENTION

The present disclosure aims primarily to provide a novel method for fabricating an organic light-emitting diode (OLED), wherein a compound with at least one substituent of a specific structure is deposited, whereby a target organic layer can be formed in the organic light-emitting diode.

In addition, the present disclosure is to provide an organic compound for organic light-emitting diodes, which allows for the deposition of target layers at lower deposition temperatures in the organic light-emitting diodes.

To achieve the technical challenges, the present disclosure provides a method for fabricating an organic light-emitting diode, the method including the steps of: forming a first electrode; forming an organic layer on the first electrode; and forming a second electrode on the organic layer,
wherein the organic layer is formed by depositing a compound for organic light-emitting diodes, the compound possessing at least one substituent represented by Structural Formula A within the molecule thereof and being deposited at a temperature more than 20° C. lower than a deposition temperature for a compound having hydrogen substituted for the substituent T in Structural Formula A when the depositing is carried out at 10⁻⁷ torr or less:

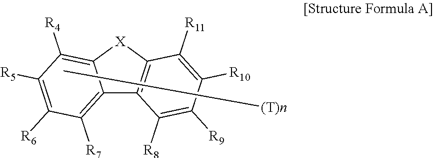

wherein,
X is O or S,
one of R₄ to R₁₁ is a single bond for bonding to an intramolecular portion other than the substituent represented by Structural Formula A in the compound for organic light-emitting diodes,
n radicals of R₄ to R₁₁ are represented by substituent (T)n, each T being a substituted or unsubstituted alkyl of 1 to 10 carbon atoms,
n is an integer of 1 to 3, wherein when n is 2 or higher, the corresponding T's are same or different,
wherein radicals of R₄ to R₁₁ other than the single bond or T are same or different and are each independently any one selected from a hydrogen atom, a deuterium atom, a substituted or unsubstituted aryl of 6 to 18 carbon atoms, and a substituted or unsubstituted alkyl of 1 to 10 carbon atoms.

Also, the present disclosure provides a polycyclic ring compound represented by the following Chemical Formula A or B:

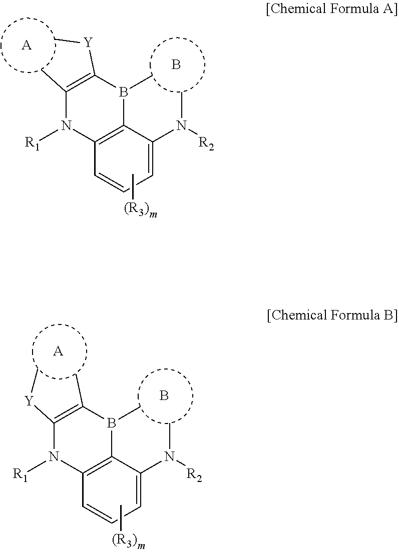

wherein,
A or B, which are same or different, are each independently a substituted or unsubstituted aromatic hydrocarbon ring of 6 to 30 carbon atoms, a substituted or unsubstituted heteroaromatic ring of 2 to 30 carbon atoms, a substituted or unsubstituted aliphatic hydrocarbon ring of 3 to 30 carbon atoms, a substituted or unsubstituted heteroaliphatic ring of 2 to 30 carbon atoms, a substituted or unsubstituted aromatic hydrocarbon ring-fused aliphatic hydrocarbon ring of 5 to 30 carbon atoms, and a substituted or unsubstituted aliphatic hydrocarbon ring-fused aromatic hydrocarbon ring of 5 to 30 carbon atoms,
Y is O or S,
R₃ is any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted alkynyl of 2 to 20 carbon atoms, a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted cycloalkyloxy of 3 to 30 carbon atoms, a substituted or unsubstituted heteroaryloxy of 2 to 30 carbon atoms, a substituted or unsubstituted akylthio of 1 to 30 carbon atoms, a substituted or unsubstituted arylthio of 6 to 30 carbon atoms, a substituted or unsubstituted cycloalkylthio of 3 to 30 carbon atoms, a substituted or unsubstituted heteroarylthio of 2 to 30 carbon atoms, a substituted or unsubstituted amine of 0 to 30 carbon atoms, a substituted or unsubstituted silyl of 0 to 30 carbon atoms, a germanium of 0 to 30 carbon atoms, a nitro, a cyano, and a halogen,
m is 3, wherein the corresponding R₃'s are same or different,
R₁ and R₂, which are same or different, are each independently any one selected from a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms, at least one of R₁ and R₂ being a substituent represented by the following Structural Formula A:

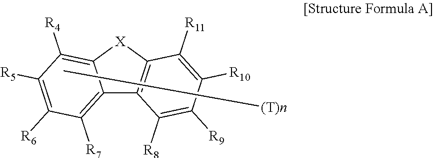

wherein,
X is O or S,
one of R₄ to R₁₁ is a single bond for bonding to an intramolecular portion other than the substituent represented by Structural Formula A in the compound for organic light-emitting diodes,
n radicals of R₄ to R₁₁ are represented by substituent (T)n, each T being a substituted or unsubstituted alkyl of 1 to 10 carbon atoms,
n is an integer of 1 to 3, wherein when n is 2 or higher, the corresponding T's are same or different,
wherein radicals of R₄ to R₁₁ other than the single bond or T are same or different and are each independently any one selected from a hydrogen atom, a deuterium atom, a substituted or unsubstituted aryl of 6 to 18 carbon atoms, and a substituted or unsubstituted alkyl of 1 to 10 carbon atoms.

Designed to deposit target layers of organic light-emitting diodes using the compound with a substituent represented by Structural Formula A, the method for fabricating an organic light-emitting diode according to the present disclosure allows a deposition process to be carried out at lower deposition temperatures, whereby the deposition material is not thermally decomposed.

In addition, the compound represented by Chemical Formula A or B according to the present disclosure allows a deposition process to be carried out at a low temperature in forming a light-emitting diode within an organic light-emitting diode, so that the materials to be deposited do not undergo thermal decomposition.

### BRIEF DESCRIPTION OF THE DRAWINGS

FIG. 1 is a schematic diagram of an organic light-emitting diode according to an embodiment of the present disclosure.

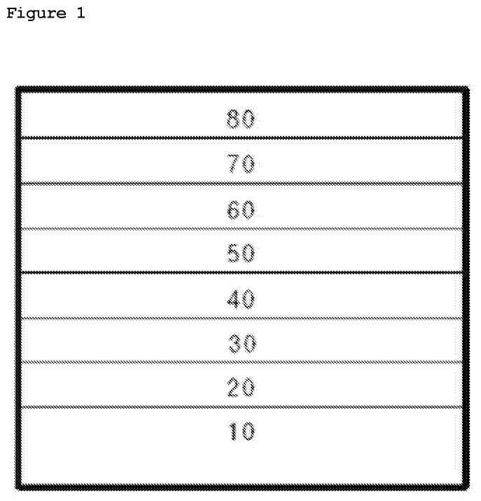

### DETAILED DESCRIPTION OF THE INVENTION

Below, a detailed description will be given of the present disclosure. In each drawing of the present disclosure, sizes or scales of components may be enlarged or reduced from their actual sizes or scales for better illustration, and known components may not be depicted therein to clearly show features of the present disclosure. Therefore, the present disclosure is not limited to the drawings. When describing the principle of the embodiments of the present disclosure in detail, details of well-known functions and features may be omitted to avoid unnecessarily obscuring the presented embodiments.

In the drawing, for convenience of description, sizes of components may be exaggerated for clarity. For example, since sizes and thicknesses of components in drawings are arbitrarily shown for convenience of description, the sizes and thicknesses are not limited thereto.

Furthermore, throughout the description, the terms “on” and “over” are used to refer to the relative positioning, and mean not only that one component or layer is directly disposed on another component or layer but also that one component or layer is indirectly disposed on another component or layer with a further component or layer being interposed therebetween. Also, spatially relative terms, such as “below”, “beneath”, “lower”, and “between” may be used herein for ease of description to refer to the relative positioning.

Throughout the specification, when a portion may “include” a certain constituent element, unless explicitly described to the contrary, it may not be construed to exclude another constituent element but may be construed to further include other constituent elements. Further, throughout the specification, the word “on” means positioning on or below the object portion, but does not essentially mean positioning on the lower side of the object portion based on a gravity direction.

The present disclosure provides a method for fabricating an organic light-emitting diode, the method including the steps of: forming a first electrode; forming an organic layer on the first electrode; and forming a second electrode on the organic layer,
wherein the organic layer is formed by depositing a compound for organic light-emitting diodes, the compound possessing at least one substituent represented by Structural Formula A within the molecule thereof and being deposited at a temperature more than 20° C. lower than a deposition temperature for a compound having hydrogen substituted for the substituent T in Structural Formula A when the depositing is carried out at 10⁻⁷ torr or less:

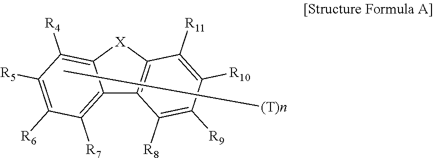

wherein,
X is O or S,
one of R₄ to R₁₁ is a single bond for bonding to an intramolecular portion other than the substituent represented by Structural Formula A in the compound for organic light-emitting diodes,
n radicals of R₄ to R₁₁ are represented by substituent (T)n, each T being a substituted or unsubstituted alkyl of 1 to 10 carbon atoms,
n is an integer of 1 to 3, wherein when n is 2 or higher, the corresponding T's are same or different, and
radicals of R₄ to R₁₁ other than the single bond or T are same or different and are each independently any one selected from a hydrogen atom, a deuterium atom, a substituted or unsubstituted aryl of 6 to 18 carbon atoms, and a substituted or unsubstituted alkyl of 1 to 10 carbon atoms,
wherein the term “substituted” in the expression “substituted or unsubstituted” used for compounds of Chemical Formula A means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, a cycloalkyl of 3 to 30 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an aromatic hydrocarbon ring-fused cycloalkyl of 7 to 24 carbon atoms, a heteroaromatic ring-fused cycloalkyl of 5 to 24 carbon atoms, an aromatic hydrocarbon ring-fused heterocycloalkyl of 6 to 24 carbon atoms, an aliphatic hydrocarbon ring-fused aryl of 8 to 24 carbon atoms, an aliphatic hydrocarbon ring-fused heteroaryl of 5 to 24 carbon atoms, an alkoxy of 1 to 24 carbon atoms, an amine of 0 to 24 carbon atoms, a silyl of 0 to 24 carbon atoms, a germanium of 0 to 24 carbon atoms, an aryloxy of 6 to 24 carbon atoms, and an arylthiony of 6 to 24 carbon atoms, and at least one hydrogen atom on the substituent may be substituted by a deuterium atom.

The expression indicating the number of carbon atoms, such as “a substituted or unsubstituted alkyl of 1 to 30 carbon atoms”, “a substituted or unsubstituted aryl of 6 to 50 carbon atoms”, etc. means the total number of carbon atoms of, for example, the alkyl or aryl radical or moiety alone, exclusive of the number of carbon atoms of substituents attached thereto. For instance, a phenyl group with a butyl at the para position falls within the scope of an aryl of 6 carbon atoms, even though it is substituted with a butyl radical of 4 carbon atoms.

As used herein, the term “aryl” means an organic radical derived from an aromatic hydrocarbon by removing one hydrogen that is bonded to the aromatic hydrocarbon. The aromatic system may include a fused ring that is formed by adjacent substituents on the aryl radical. In addition, the aryl may include an organic radical obtained by removing one hydrogen from a fused arene ring in which two arene rings are fused to each other.

Concrete examples of the aryl include aromatic radicals such as phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, fluoranthenyl, triperylenyl, but are not limited thereto. Organic radicals resulting from the removal of one hydrogen atom from fused rings between two arene rings, such as fluorene and phenylene rings, fluorene and phenanthrene rings, etc., are also included.

In addition, the aryl radical may have, as a substituent, at least one selected from a deuterium atom, a halogen atom, a hydroxy, a hydroxy, a nitro, a cyano, a silyl, an amine, a germanium, an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 3 to 24 carbon atoms, and an alkylheteroaryl of 3 to 24 carbon atoms.

As used herein, the term “aromatic hydrocarbon ring” refers to an aromatic ring composed of carbon and hydrogen atoms and the term “aliphatic hydrocarbon ring” refers to a hydrocarbon ring that is composed of carbon and hydrogen atoms, but does not belong to the aromatic hydrocarbon rings. Particularly, the aliphatic hydrocarbon ring may have a bonding structure of the sp³ orbital for at least 30% of the carbon atoms as ring members, with 0 to 3 double and/or triple bonds within the ring. More particularly, the aliphatic hydrocarbon ring may have a bonding structure of the sp³ orbital for at least 50% of the carbon atoms as ring members, with 0 to 3 double and/or triple bonds within the ring.

The term “aliphatic hydrocarbon ring-fused aryl”, as used herein, refers to a cyclic radical in which two adjacent carbon atoms as ring members of an aliphatic hydrocarbon ring and two adjacent carbon atoms as ring members of an aryl are fused with each other to share one double bond therebetween, with non-aromaticity across the molecule. Concrete examples include, but are not limited to, tetrahydronaphthyl, tetrahydrobenzocycloheptene, tetrahydrophenanthrene, tetrahydroanthracenyl, and octahydrotriphenylene.

The substituent “heteroaryl” used in the compound of the present disclosure means a hetero aromatic radical of 2 to 24 carbon atoms, bearing as ring member(s) one to three heteroatoms selected from among N, O, P, Si, S, Ge, Se, and Te. In the aromatic radical, two or more rings may be fused. One or more hydrogen atoms on the heteroaryl may be substituted by the same substituents as on the aryl.

Concrete examples of the heteroaryl include thiophenyl, furanyl, pyrrolyl, imidazolyl, thiazolyl, oxazolyl, oxadiazolyl, triazolyl, pyridinyl, bipyridinyl, pyrimidinyl, triazinyl, triazolyl, acridinyl, carbolinyl, acenaphthoquinolinyl, indenoquinolinyl, indenoisoquinolinyl, indenoquinolinyl, pyridoindolyl, pyridazinyl, pyrazinyl, quinolinyl, quinazolinyl, quinoxalinyl, phthalazinyl, pyridopyrimidinyl, pyridopyrazinyl, pyrazinopyrazinyl, isoquinolinyl, indolyl, carbazolyl, benzoxazolyl, benzimidazolyl, benzothiazolyl, benzocarbazolyl, benzofuranyl, benzothiophenyl, benzoselenophenyl, dibenzothiophenyl, dibenzofuranyl, dibenzoselenophenyl, phenanthrolinyl, thiazolinyl, iso-oxazolyl, oxadiazolyl, thiadiazolyl, benzothiazolyl, phenoxazinyl, phenothiazinyl, azadibenzofuryl, azadibenzothiophenyl, azadibenzoselenophenyl, and indolocarbazolyl, but are not limited to these.

In addition, the term “heteroaromatic ring”, as used herein, refers to an aromatic hydrocarbon ring bearing at least one heteroatom as aromatic ring member. In the heteroaromatic ring, one to three carbon atoms of the aromatic hydrocarbon may be substituted by at least one selected particularly from N, O, P, Si, S, Ge, Se, and Te.

The term “aliphatic hydrocarbon ring-fused heteroaryl” is same as “aliphatic hydrocarbon ring-fused aryl”, with the exception that the aryl is substituted by a heteroaryl. Concrete examples include, but are not limited to, tetrahydroindol, tetrahydrobenzofuranyl, tetrahydrobenzothiophene, tetrahydrocarbazole, tetrahydrodibenzofuranyl, tetrahydrobenzothiophene, tetrahydroquinoline, and tetrahydroquinoxaline.

In addition, the term “heteroaromatic ring”, as used herein, refers to an aromatic hydrocarbon ring bearing at least one heteroatom as an aromatic ring member. In the heteroaromatic ring, one to three carbon atoms of the aromatic hydrocarbon may be substituted by at least one selected particularly from N, O, P, Si, S, Ge, Se, and Te.

In the present disclosure, the term “fused ring with an aromatic hydrocarbon ring and an aliphatic hydrocarbon ring fused to each other” refer to a cyclic radical in which two adjacent carbon atoms as ring members of an aromatic hydrocarbon ring and two adjacent carbon atoms as ring members of an aliphatic hydrocarbon ring are fused with each other to share two carbon atoms therebetween, as exemplified by tetrahydronaphthalene in which a benzene ring and a cyclohexane ring are fused by sharing their respective two adjacent carbon atoms as ring members, dihydroindene ring, etc.

As used herein, the term “fused ring with a heteroaromatic ring and an aliphatic hydrocarbon ring fused to each other” refers to a cyclic radical in which two adjacent carbon atoms as ring members of a heteroaromatic hydrocarbon ring and two adjacent carbon atoms of aliphatic hydrocarbon ring are fused with each other to share two carbon atoms therebetween, as exemplified by a hexahydrodibenzofuran ring in which a benzofuran ring and a cyclohexane ring are fused by sharing their respective two adjacent carbon atoms as ring members.

As used herein, the term “alkyl” refers to an alkane missing one hydrogen atom and includes linear or branched structures. Examples of the alkyl substituent include methyl, ethyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cycloheptylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, and 5-methylhexyl, but are not limited thereto. At least one hydrogen atom of the alkyl may be substituted by the same substituent as in the aryl.

The term “halogenated alkyl” refers to an alkyl with at least one halogen atom as a substituent therein. Preferably the halogen atom may be a fluorine atom.

The term “cyclo” as used in substituents of the compounds of the present disclosure, such as cycloalkyl, cycloalkoxy, etc., refers to a structure responsible for a mono- or polycyclic ring of saturated hydrocarbons. Concrete examples of cycloalkyl radicals include cyclopropyl, cyclobutyl, cyclopentyl, cyclohexyl, methylcyclopentyl, methylcyclohexyl, ethylcyclopentyl, ethylcyclohexyl, adamantyl, dicyclopentadienyl, decahydronaphthyl, norbornyl, bornyl, isobornyl, and so on. One or more hydrogen atoms on the cycloalkyl may be substituted by the same substituents as on the aryl.

In the present disclosure, the term “heterocycloalkyl” refers to a cycloalkyl with at least one heteroatom substituted as a ring member for a carbon atom within the ring. Preferably, one to three carbon atoms within the ring may be substituted by at least one selected from N, O, P, S, Si, Ge, Se, and Te.

The aromatic hydrocarbon ring- or heteroaromatic ring-fused cycloalkyl refers to a cyclic radical in which two adjacent carbon atoms as ring members of an aromatic or heteroaromatic hydrocarbon ring and two adjacent carbon atoms as ring members of a cycloalkyl are fused with each other to share one double bond therebetween, with non-aromaticity across the molecule. Concrete examples include, but are not limited to, tetrahydronaphthyl, tetrahydrophenanthrene, tetrahydroquinolone, tetrahydroquinoxaline, and cyclopentabenzofurane.

The term “aromatic hydrocarbon ring-heterocyclic alkyl” is same as the aromatic hydrocarbon ring-fused cycloalkyl, with the exception that at least one carbon atom within the cycloalkyl ring is substituted by a heteroatom, with non-aromaticity across the molecule. Preferably, one to three carbon atoms within the cycloalkyl ring are substituted by at least one selected from N, O, P, S, Si, Ge, Se, and Te. Concrete examples of aromatic hydrocarbon ring-heterocyclic alkyl include, but are not limited to, hexahydrodibenzofuranyl, hexahydrocarbozole, hexahydrodibenzothiophene, and dihydrobenzodioxine.

As used herein, the “heteroaliphatic ring-fused aryl or heteroaryl” is same as the aliphatic hydrocarbon ring-fused aryl or heteroaryl, except for a heteroaliphatic ring substituted for the aliphatic hydrocarbon ring, with non-aromaticity across the molecule thereof. Concrete examples include cromane, dihydropyranopyridine, thiocromane, dihydrobenzodioxine, dihydrothiopyranopyridine, and dihydropyranopyrimidine.

The term “heteroaliphatic ring” refers to an aliphatic hydrocarbon bearing at least one heteroatom as a ring member. Preferably, one to three carbon atoms within an aliphatic hydrocarbon are substituted by at least one heteroatom selected from N, O, and S.

The term “alkoxy” as used in the compounds of the present disclosure refers to an alkyl or cycloalkyl singularly bonded to oxygen. Concrete examples of the alkoxy include methoxy, ethoxy, propoxy, isobutoxy, sec-butoxy, pentoxy, iso-amyloxy, hexyloxy, cyclobutyloxy, cyclopentyloxy, adamantyloxy, dicyclopentyloxy, bornyloxy, isobornyloxy, and the like. One or more hydrogen atoms on the alkoxy may be substituted by the same substituents as on the aryl.

Concrete examples of the arylalkyl used in the compounds of the present disclosure include phenylmethyl(benzyl), phenylethyl, phenylpropyl, naphthylmethyl, naphthylethyl, and the like. One or more hydrogen atoms on the arylalkyl may be substituted by the same substituents as on the aryl.

Concrete examples of the alkylaryl used in the compounds of the present disclosure include tolyl, xylenyl, t-butylphenyl, t-butylnaphthyl, t-butylphenanthryl, and the like. One or more hydrogen atoms on the alkylaryl may be substituted by the same substituents as on the aryl.

As used herein, the term “alkenyl” refers to an alkyl substituent containing a carbon-carbon double bond between two carbon atoms and the term “alkynyl” refers to an alkyl substituent containing a carbon-carbon triple bond between two carbon atoms.

As used herein, the term “alkylene” refers to an organic radical regarded as derived from an alkane by removal two hydrogen atoms from one carbon atom for methylene or different carbon atoms for ethylene or higher, such as propylene, isopropylene, isobutylene, sec-butylene, tert-butylene, pentylene, iso-amylene, hexylene, and the like. One or more hydrogen atoms on the alkylene may be substituted by the same substituents as on the aryl.

In the present disclosure, the term “amine” is intended to encompass —NH₂, alkylamine, arylamine, alkylarylamine, arylheteroarylamine, heteroarylamine, and the like. The arylamine refers to an amine radical obtained by substituting one or two of the hydrogen atoms in —NH₂ with aryl groups. The alkylamine refers to an amine group obtained by substituting one or two of the hydrogen atoms in —NH₂ with alkyl groups. The alkylarylamine refers to an amine group obtained by substituting one of the hydrogen atoms in —NH₂ with an alkyl group and the other hydrogen atom with an aryl group. The arylheteroarylamine refers to an amine group obtained by substituting one of the hydrogen atoms in —NH₂ with an aryl group and the other hydrogen atom with a heteroaryl group. The heteroarylamine refers to an amine group obtained by substituting one or two of the hydrogen atoms in —NH₂ with heteroaryl groups. The arylamine may be, for example, substituted or unsubstituted monoarylamine, substituted or unsubstituted diarylamine, or substituted or unsubstituted triarylamine. The same applies to the alkylamine and heteroarylamine groups.

Each of the aryl radicals in the arylamine, heteroarylamine, and arylheteroarylamine may be a monocyclic or polycyclic one. Each of the heteroaryl radicals in the arylamine, heteroarylamine, and arylheteroarylamine may be a monocyclic or polycyclic one.

The silyl radical used in the compounds of the present disclosure is intended to encompass —SiH₃, alkylsilyl, arylsilyl, alkylarylsilyl, arylheteroarylsilyl, and heteroarylsilyl. The arylsilyl refers to a silyl group obtained by substituting one, two, or three of the hydrogen atoms in —SiH₃ with aryl groups. The alkylsilyl refers to a silyl group obtained by substituting one, two or three of the hydrogen atoms in —SiH₃ with alkyl groups. The alkylarylsilyl refers to a silyl group obtained by substituting one of the hydrogen atoms in —SiH₃ with an alkyl group and the other two hydrogen atoms with aryl groups or substituting two of the hydrogen atoms in —SiH₃ with alkyl groups and the remaining hydrogen atom with an aryl group. The arylheteroarylsilyl refers to a silyl group obtained by substituting one of the hydrogen atoms in —SiH₃ with an aryl group and the other two hydrogen atoms with heteroaryl groups or substituting two of the hydrogen atoms in —SiH₃ with aryl groups and the remaining hydrogen atom with a heteroaryl group. The heteroarylsilyl refers to a silyl group obtained by substituting one, two or three of the hydrogen atoms in —SiH₃ with heteroaryl groups. The arylsilyl group may be, for example, substituted or unsubstituted monoarylsilyl, substituted or unsubstituted diarylsilyl, or substituted or unsubstituted triarylsilyl. The same applies to the alkylsilyl and heteroarylsilyl groups.

Here, each of the aryl groups in the arylsilyl, heteroarylsilyl, and arylheteroarylsilyl groups may be a monocyclic or polycyclic one. Each of the heteroaryl groups in the arylsilyl, heteroarylsilyl, and arylheteroarylsilyl groups may be a monocyclic or polycyclic one

Specific examples of the silyl groups include trimethylsilyl, triethylsilyl, triphenylsilyl, triphenylsilyl, trimethoxysilyl, dimethoxyphenylsilyl, diphenylmethylsilyl, diphenylvinylsilyl, methylcyclobutylsilyl, and dimethylfurylsilyl. One or more of the hydrogen atoms in each of the silyl groups may be substituted with the substituents mentioned in the aryl groups.

As used herein, the term “germanium” (or germyl or germane) is intended to encompass —GeH₃, an alkyl germanium, an aryl germanium, a heteroaryl germanium, an alkylaryl germanium, an alkylheteroaryl germanium, an arylheteroaryl germanium, and the like. They can be accounted for by the definitions for silyl radicals, with the exception that the silicone atom (Si) in the silyl radical is substituted by a germanium atom (Ge).

Concrete examples of the germanium radical include trimethylgermane, triethylgermane, triphenylgermane, trimethoxygermane, dimethoxyphenylgermane, diphenylmethylgermane, diphenylvinylgermane, methylcyclobutylgermane, and dimethylfurylgermane. One or more hydrogen atoms on the germanium radical may be substituted by the same substituents as on the aryl.

As used herein, the substituent (B) adjacent to a substituent (A) within an aromatic ring means a substituent (B) bonded to a carbon atom(s) as a ring member(s) adjacent to a carbon atom as a ring member having the substituent (A) bonded thereto, within the aromatic ring. Also, the substituent (B) adjacent to a substituent (A) within an aliphatic ring means a substituent (B) bonded to a carbon atom(s) as a ring member(s) adjacent to a carbon atom as a ring member having the substituent (A) bonded thereto, within the aliphatic ring. Further, the substituent (B) adjacent to a substituent (A) within an aliphatic chain structure means a substituent (B) bonded to a carbon atom(s) as a ring member(s) adjacent to a carbon atom as a ring member having the substituent (A) bonded thereto, within the aliphatic chain structure.

In a preferable embodiment, the substituent counted for by the term “substituted” in the expression “substituted or unsubstituted” used for compounds of Chemical Formula A may be at least one selected from the group consisting of a deuterium atom, a cyano, a halogen, a hydroxy, a nitro, an alkyl of 1 to 12 carbon atoms, a halogenated alkyl of 1 to 12 carbon atoms, an alkenyl of 2 to 12 carbon atoms, an alkynyl of 2 to 12 carbon atoms, a cycloalkyl of 3 to 12 carbon atoms, a heteroalkyl of 1 to 12 carbon atoms, an aryl of 6 to 18 carbon atoms, an arylalkyl of 7 to 20 carbon atoms, an alkylaryl of 7 to 20 carbon atoms, a heteroaryl of 2 to 18 carbon atoms, a heteroarylalkyl of 3 to 18 carbon atoms, an alkylheteroaryl of 3 to 18 carbon atoms, an aromatic hydrocarbon ring-fused cycloalkyl of 9 to 20 carbon atoms, a heteroaromatic ring-fused cycloalkyl of 7 to 20 carbon atoms, an aromatic hydrocarbon ring-fused heterocycloalkyl of 9 to 20 carbon atoms, an aliphatic hydrocarbon ring-fused aryl of 9 to 20 carbon atoms, an aliphatic hydrocarbon ring-fused heteroaryl of 7 to 20 carbon atoms, an alkoxy of 1 to 12 carbon atoms, an amine of 1 to 18 carbon atoms, a silyl of 1 to 18 carbon atoms, a germanium of 1 to 18, an aryloxy of 6 to 18 carbon atoms, and an arylthionyl of 6 to 18 carbon atoms 6. The substituent may have deuterium atom, instead of at least one hydrogen atom, bonded thereto.

In a more preferable embodiment of the present disclosure, the substituted or unsubstituted aromatic hydrocarbon ring-fused cycloalkyl of 7 to 30 carbon atoms may be a substituted or unsubstituted aromatic hydrocarbon ring-fused cycloalkyl of 9 to 20 carbon atoms.

In a more preferable embodiment of the present disclosure, the substituted or unsubstituted heteroaromatic ring-fused cycloalkyl of 5 to 30 carbon atoms may be a substituted or unsubstituted heteroaromatic ring-fused cycloalkyl of 7 to 20 carbon atoms.

In a more preferable embodiment of the present disclosure, the substituted or unsubstituted aromatic hydrocarbon ring-fused heterocycloalkyl of 7 to 30 carbon atoms may be a substituted or unsubstituted aromatic hydrocarbon ring-fused heterocycloalkyl of 9 to 20 carbon atoms.

In a more preferable embodiment of the present disclosure, the substituted or unsubstituted aliphatic hydrocarbon ring-fused aryl of 8 to 30 carbon atoms may be a substituted or unsubstituted aliphatic hydrocarbon ring-fused aryl of 9 to 20 carbon atoms.

In a more preferable embodiment of the present disclosure, the substituted or unsubstituted aliphatic hydrocarbon ring-fused heteroaryl of 5 to 30 carbon atoms may be a substituted or unsubstituted aliphatic hydrocarbon ring-fused heteroaryl of 7 to 20 carbon atoms.

In a more preferable embodiment of the present disclosure, the substituted or unsubstituted heteroaliphatic ring-fused aryl of 6 to 30 carbon atoms may be a substituted or unsubstituted heteroaliphatic ring-fused aryl of 7 to 20 carbon atoms.

In a more preferable embodiment of the present disclosure, the substituted or unsubstituted heteroaliphatic ring-fused heteroaryl of 5 to 30 carbon atoms may be a substituted or unsubstituted heteroaliphatic ring-fused heteroaryl of 6 to 20 carbon atoms.

The method for fabricating an organic light-emitting diode according to the present disclosure is characterized by the technical feature wherein, when any one organic layer selected from an electron injection layer, a hole injection layer, a hole transport layer, an electron blocking layer, a functional layer capable of both hole injection and hole transport, a light-emitting layer, an electron transport layer, an electron injection layer, a hole blocking layer, and a functional layer capable of both electron injection and electron transport within the organic light-emitting diode is formed, an organic compound possessing at least one substituent represented by Structural Formula A within the molecule thereof is used as a deposition material and can be deposited at a temperature more than 20° C. lower than a deposition temperature for a compound having hydrogen substituted for the substituent T in Structural Formula A under the condition of 10⁻⁷ torr or less.

Here, the organic compound possessing a substituent represented by Structural Formula A is used as a material for the deposition of an organic layer within organic light-emitting diodes. So long as it possesses at least one substituent represented by Structural Formula A within the molecule thereof, any organic compound may be used in the present disclosure. Preferably, the organic compound may possess one to five, more preferably one to three, and even more preferably one or two of the substituents represented by Structural Formula A.

The organic compound possessing the substituent represented by Structural Formula A in which one to three of R₄ to R₁₁ are accounted for by the substituent T, which is a substituted or unsubstituted alkyl of 1 to 10 carbon atoms, can be deposited at a temperature more than 20° C. lower than a deposition temperature for a compound having a hydrogen atom, instead of the substituent T, bonded thereto under the condition of 10⁻⁷ torr or less.

Here, one of R₄ to R₁₁ in Structural Formula A is a single bond responsible for the remaining moiety of the molecule of the organic compound for use in forming an organic layer, wherein the “remaining moiety” of the molecule of the organic compound accounts for the portion of the molecule which is other than and is connected to the substituent represented by Structural Formula A. Typically, it may be a hydrocarbon ring compound or a heteroring compound bearing one to five heteroatoms selected from N, O, S, and P and its molecular structural formula may depend on types of the organic layer to be deposited.

As used herein, the term “deposition temperature” refers to a temperature within a crucible at which a deposition material to be deposited in a vacuum or at a reduced pressure in a deposition chamber is heated to form a specific layer on a substrate or a preexisting layer within an organic light-emitting diode through sublimation or vaporization in the crucible to which the deposition material is introduced. A deposition material is apt to be damaged and thermally decomposed when it stays long within the crucible given a high decomposition temperature. Thus, the deposition temperature is preferably set to be as low as possible.

In the method for fabricating an organic light-emitting diode according to an embodiment of the present disclosure, the compound with a compound represented by Structural Formula A may have a molecular weight of 900 or higher, preferably a molecular weight of 900 to 2,500, and more preferably a molecular weight of 900 to 1,500.

In the method for fabricating an organic light-emitting diode according to an embodiment of the present disclosure, the organic layer may be any one selected from an electron injection layer, a hole injection layer, a hole transport layer, an electron blocking layer, a functional layer capable of both hole injection and hole transport, a light-emitting layer, an electron transport layer, an electron injection layer, a hole blocking layer, and a functional layer capable of both electron injection and electron transport.

In the method for fabricating an organic light-emitting diode according to an embodiment of the present disclosure, the organic layer may be a light-emitting layer. In a preferable embodiment, the organic layer is a light-emitting layer composed of a host and a dopant, wherein the compound with a substituent represented by Structural Formula A is used as the dopant.

The present disclosure provides a method for fabricating an organic light-emitting diode, the method including the steps of: forming a first electrode; forming an organic layer on the first electrode; and forming a second electrode on the organic layer, wherein the organic layer is a light-emitting layer and is composed of a host and a dopant and a compound with at least one substituent represented by Structural Formula A is used as the dopant in the light-emitting layer.

In an embodiment, R₇ in the compound possessing the substituent represented by Structural Formula A may be a single bond through which the substituent is connected to the remaining portion of the molecule of the compound.

In an embodiment, T in the substituent represented by Structural Formula A within the compound for organic light-emitting diodes may be an alkyl of 3 to 10 carbon atoms with or without a deuterium or halogen atom as a substituent and preferably an alkyl of 3 to 8 carbon atoms with or without a deuterium or fluorine atom (F) as a substituent.

In the method for fabricating an organic light-emitting diode according to an embodiment of the present disclosure, the compound with a substituent represented by Structural Formula A may be a polycyclic ring compound represented by the following Chemical Formula A or B:

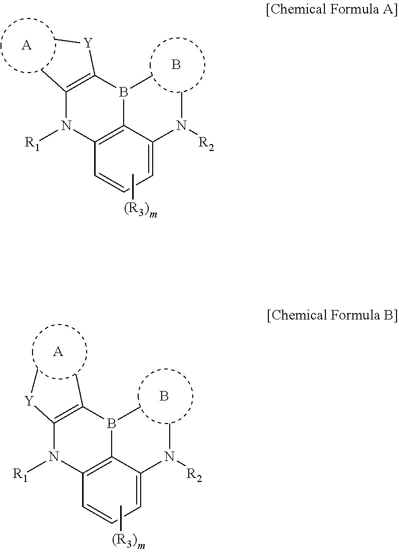

wherein,
A and B, which are same or different, are each independently a substituted or unsubstituted aromatic hydrocarbon ring of 6 to 30 carbon atoms, a substituted or unsubstituted heteroaromatic ring of 2 to 30 carbon atoms, a substituted or unsubstituted aliphatic hydrocarbon ring of 3 to 30 carbon atoms, a substituted or unsubstituted heteroaliphatic ring of 2 to 30 carbon atoms, a substituted or unsubstituted aromatic hydrocarbon ring-fused aliphatic hydrocarbon ring of 5 to 30 carbon atoms, and a substituted or unsubstituted aliphatic hydrocarbon ring-fused aromatic hydrocarbon ring of 5 to 30 carbon atoms,
Y is O or S,
R₃ is any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted alkynyl of 2 to 20 carbon atoms, a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted cycloalkyloxy of 3 to 30 carbon atoms, a substituted or unsubstituted heteroaryloxy of 2 to 30 carbon atoms, a substituted or unsubstituted akylthio of 1 to 30 carbon atoms, a substituted or unsubstituted arylthio of 6 to 30 carbon atoms, a substituted or unsubstituted cycloalkylthio of 3 to 30 carbon atoms, a substituted or unsubstituted heteroarylthio of 2 to 30 carbon atoms, a substituted or unsubstituted amine of 0 to 30 carbon atoms, a substituted or unsubstituted silyl of 0 to 30 carbon atoms, a germanium of 0 to 30 carbon atoms, a nitro, a cyano, and a halogen,
m is 3, wherein the corresponding R₃'s are same or different,
R₁ and R₂, which are same or different, are each independently any one selected from a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms, at least one of R₁ and R₂ being a substituent represented by the following Structural Formula A:

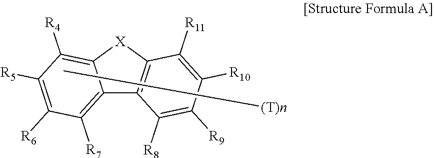

wherein,
X is O or S,
one of R₄ to R₁₁ is a single bond for bonding to a nitrogen atom,
n radicals of R₄ to R₁₁ are represented by substituent (T)n, each
T being a substituted or unsubstituted alkyl of 1 to 10 carbon atoms,
n is an integer of 1 to 3, wherein when n is 2 or higher, the corresponding T's are same or different,
wherein radicals of R₄ to R₁₁ other than the single bond or T are same or different and are each independently any one selected from a hydrogen atom, a deuterium atom, a substituted or unsubstituted aryl of 6 to 18 carbon atoms, and a substituted or unsubstituted alkyl of 1 to 10 carbon atoms,
wherein the term “substituted” in the expression “substituted or unsubstituted” used for compounds of Chemical Formulas A and B and Structural Formula A means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, cycloalkyl of 3 to 30 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an aromatic hydrocarbon ring-fused cycloalkyl of 7 to 24 carbon atoms, a heteroaromatic ring-fused cycloalkyl of 5 to 24 carbon atoms, an aromatic hydrocarbon ring-fused heterocycloalkyl of 6 to 24 carbon atoms, an aliphatic hydrocarbon ring-fused aryl of 8 to 24 carbon atoms, an aliphatic hydrocarbon ring-fused heteroaryl of 5 to 24 carbon atoms, an alkoxy of 1 to 24 carbon atoms, an amine of 0 to 24 carbon atoms, a silyl of 0 to 24 carbon atoms, a germanium of 0 to 24 carbon atoms, an aryloxy of 6 to 24 carbon atoms, and an arylthionyl of 6 to 24 carbon atoms, and at least one hydrogen atom on the substituent may be substituted by a deuterium atom.

In an embodiment, at least one of R₁ and R₂ in the compound represented by Chemical Formula A or B may be a substituent represented by Structural Formula A, and preferably only R₂ may be a substituent represented by Structural Formula A.

In an embodiment, the ring moieties A and B in the compound represented by Chemical Formula A or B may each be independently a substituted or unsubstituted aromatic hydrocarbon ring of 6 to 20 carbon atoms and preferably a substituted or unsubstituted aromatic hydrocarbon ring of 6 to 14 carbon atoms.

In an embodiment, n in the compound represented by Chemical Formula A or B is 1 or 2 so that the compound represented by Chemical Formula A or B may possess one or two T's, which are each a substituted or unsubstituted alkyl of 1 to 10 carbon atoms. Preferably, n is 1 so that the compound represented by Chemical Formula A or B may possess one T which is an alkyl of 1 to 10 carbon atoms with or without a deuterium atom as a substituent.

In an embodiment, R₇ within Structural Formular A of the compound represented by Chemical Formula A or B may be a single bond to a nitrogen atom.

In an embodiment, one or two of R₈ to R₁₁ in Structural Formular A of the compound represented by Chemical Formula A or B are accounted for by T, which is a substituted or unsubstituted alkyl of 1 to 10 carbon atoms, and preferably R₉ may be accounted for by T.

In an embodiment, T in Structural Formular A of the compound represented by Chemical Formula A or B may be an alkyl of 1 to 10 carbon atoms with or without a deuterium atom as a substituent.

In an embodiment, R₃ in the compound represented by Chemical Formula A or B may be a substituted or unsubstituted silyl of 1 to 30 carbon atoms.

In an embodiment, the compound represented by Chemical Formula A or B may have a deposition temperature of 180° C. or lower.

Moreover, concrete examples of the polycyclic compound represented by Chemical Formula A or B in the method for fabricating an organic light-emitting diode according to the present disclosure include, but are not limited to, the following Compounds 1 to 18:

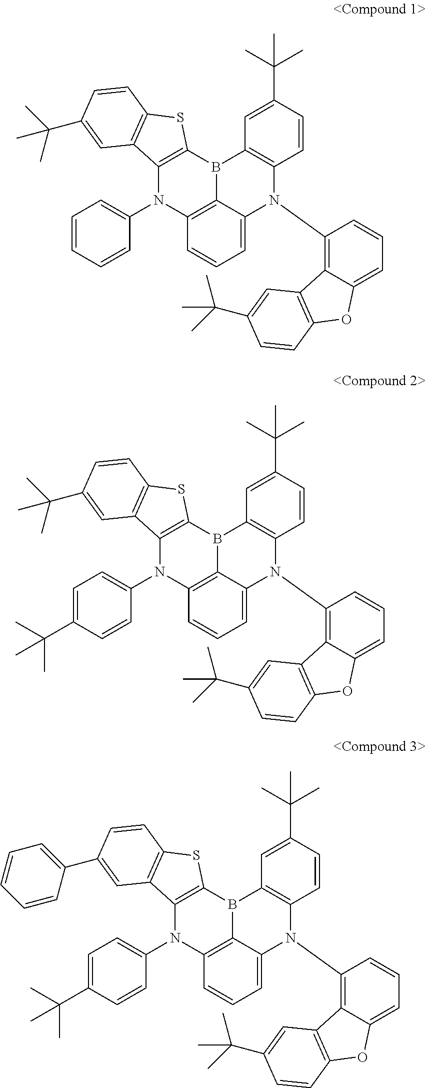 [SMILES: CC(C)(C)c1ccc2c(c1)B1c3sc4ccc(C(C)(C)C)cc4c3N(c3ccccc3)c3cccc(c31)N2c1cccc2oc3ccc(C(C)(C)C)cc3c12 ; CC(C)(C)c1ccc(N2c3cccc4c3B(c3cc(C(C)(C)C)ccc3N4c3cccc4oc5ccc(C(C)(C)C)cc5c34)c3sc4ccc(C(C)(C)C)cc4c32)cc1 ; CC(C)(C)c1ccc(N2c3cccc4c3B(c3cc(C(C)(C)C)ccc3N4c3cccc4oc5ccc(C(C)(C)C)cc5c34)c3sc4ccc(-c5ccccc5)cc4c32)cc1]

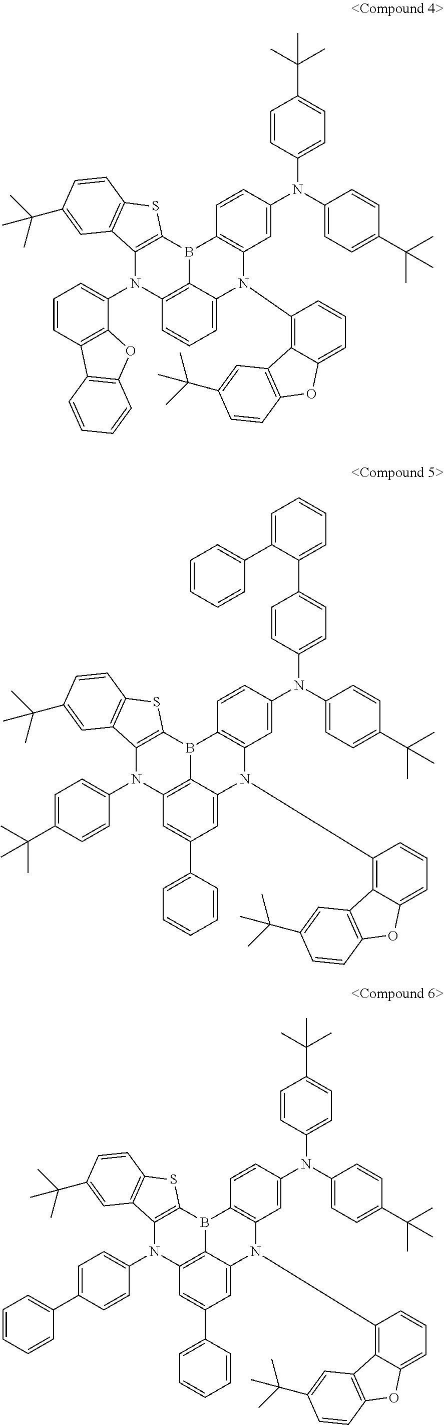

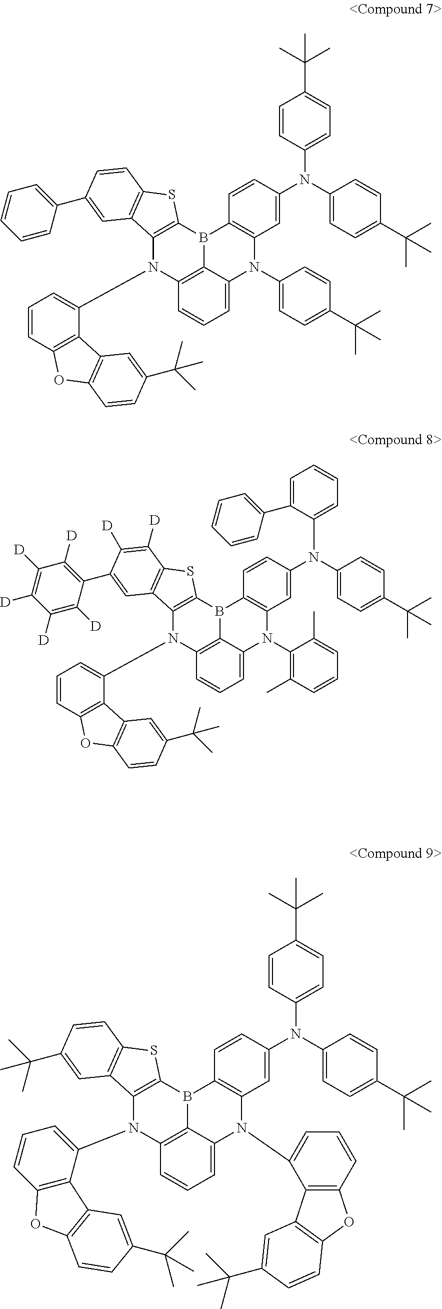

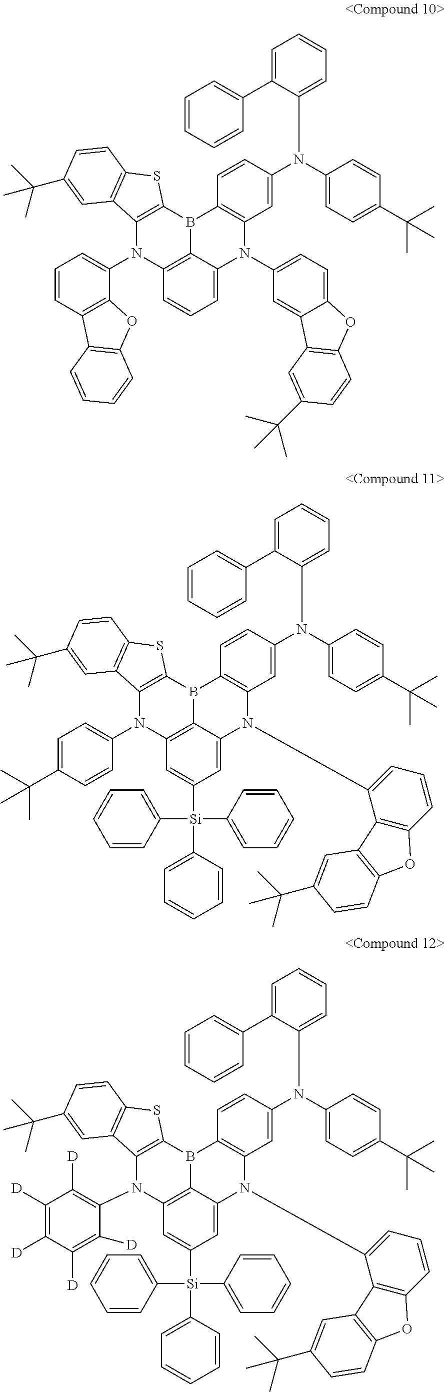

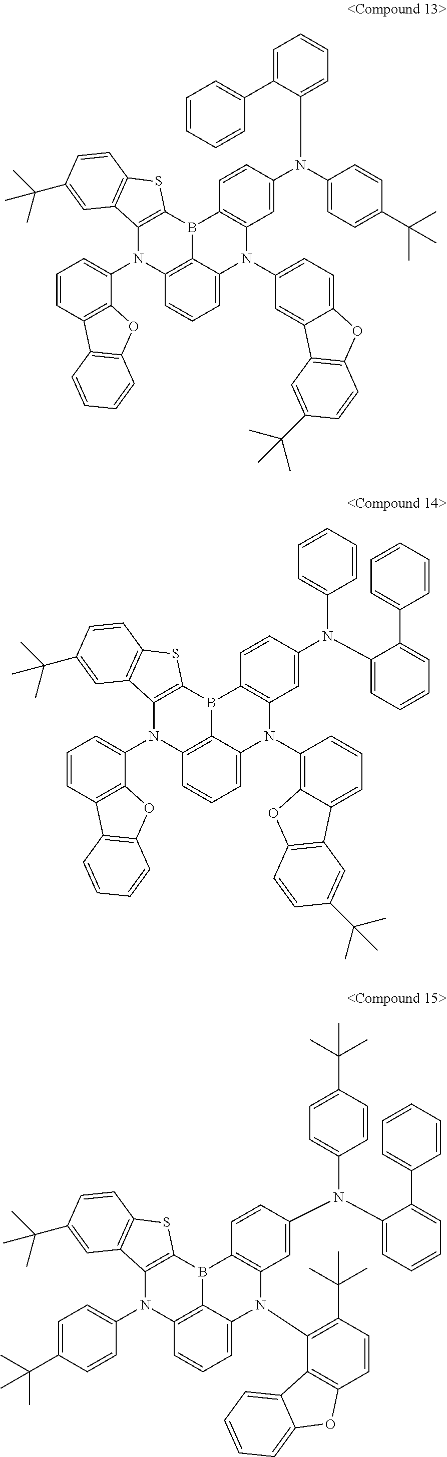

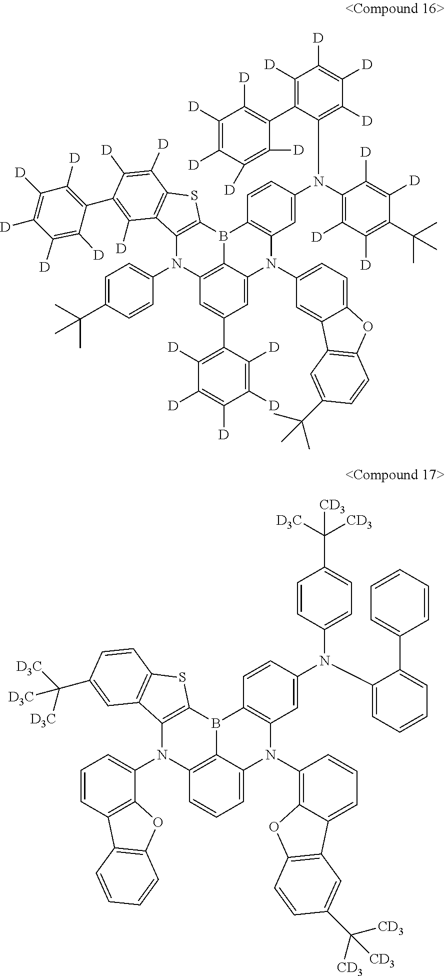

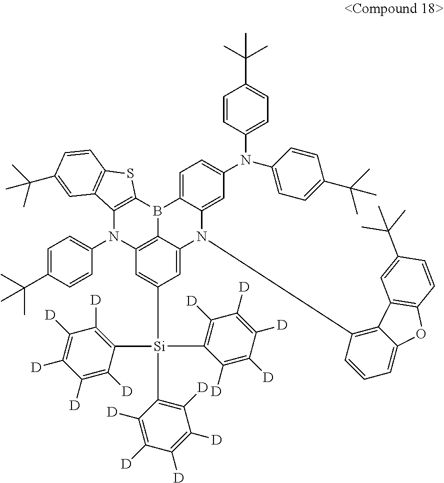 [SMILES: [2H]c1c([2H])c([2H])c([Si](c2cc3c4c(c2)N(c2cccc5oc6ccc(C(C)(C)C)cc6c25)c2cc(N(c5ccc(C(C)(C)C)cc5)c5ccc(C(C)(C)C)cc5)ccc2B4c2sc4ccc(C(C)(C)C)cc4c2N3c2ccc(C(C)(C)C)cc2)(c2c([2H])c([2H])c([2H])c([2H])c2[2H])c2c([2H])c([2H])c([2H])c([2H])c2[2H])c([2H])c1[2H]]

In a more preferably embodiment, the present disclosure provides a method for fabricating an organic light-emitting diode, the method including the steps of: forming a first electrode; forming an organic layer on the first electrode; and forming a second electrode on the organic layer, wherein the organic layer disposed between the first electrode and the second electrode includes a light-emitting layer, the light-emitting diode is composed of a host and a dopant, and at least one of the compounds possessing a substituent represented by Structural Formula A is deposited as a dopant within the light-emitting layer.

In this regard, the host within the light-emitting layer may be formed by depositing an anthracene derivative represented by the following Chemical Formula D:

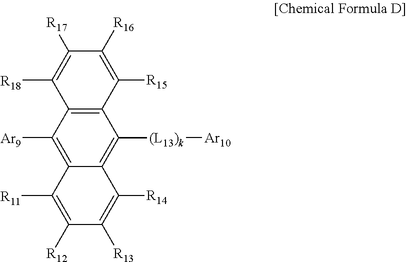

wherein,
R₁₁ to R₁₈, which are same or different, are each independently any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted alkynyl of 2 to 20 carbon atoms, a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted cycloalkyloxy of 3 to 30 carbon atoms, a substituted or unsubstituted heteroaryloxy of 2 to 30 carbon atoms, a substituted or unsubstituted akylthio of 1 to 30 carbon atoms, a substituted or unsubstituted arylthio of 6 to 30 carbon atoms, a substituted or unsubstituted cycloalkylthio of 3 to 30 carbon atoms, a substituted or unsubstituted heteroarylthio of 2 to 30 carbon atoms, a substituted or unsubstituted amine of 0 to 30 carbon atoms, a substituted or unsubstituted silyl of 0 to 30 carbon atoms, a germanium of 0 to 30 carbon atoms, a nitro, a cyano, and a halogen,
Ar₉ and Ar₁₀, which are same or different, are each independently any one selected from a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl of 2 to 20 carbon atoms, a substituted or unsubstituted cycloalkyl of 3 to 30 carbon atoms, a substituted or unsubstituted cycloalkenyl of 5 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylamine of 1 to 30 carbon atoms, a substituted or unsubstituted arylamine of 6 to 30 carbon atoms, a substituted or unsubstituted alkylsilyl of 1 to 30 carbon atoms, a substituted or unsubstituted arylsilyl of 6 to 30 carbon atoms;
L₁₃ is any one selected from a single bond, a substituted or unsubstituted arylene of 6 to 20 carbon atoms, and a substituted or unsubstituted heteroarylene of 2 to 20 carbon atoms, and
k is an integer of 1 to 3, wherein when k is 2 or higher, the corresponding L₁₃'s are same or different,
wherein the term “substituted” in the expression “substituted or unsubstituted” is as defined above.

In a preferable embodiment, the linker L₁₃ is a single bond or a substituted or unsubstituted arylene of 6 to 20 carbon atoms, and k is an integer of 1 to 2, wherein when k is 2, the corresponding L₁₃'s are same or different.

Furthermore, Ar₉ in the host compound represented by Chemical Formula D may be a substituent represented by Chemical Formula D-1, below:

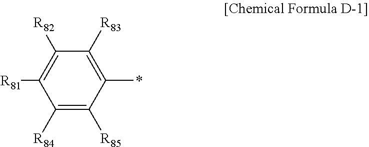

wherein R₈₁ to R₈₅, which are same or different, are as defined for R₁₁ to R₁₈ above, and may each be linked to an adjacent one to form a saturated or unsaturated ring.

According to an embodiment, the anthracene derivative may be any one selected from the compounds represented by the following [Chemical Formula D1] to [Chemical Formula D48]:

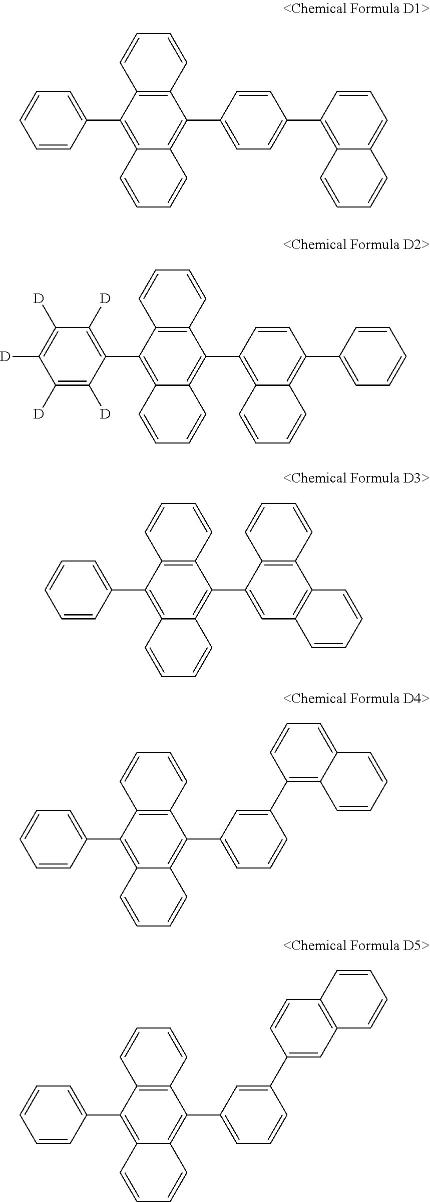

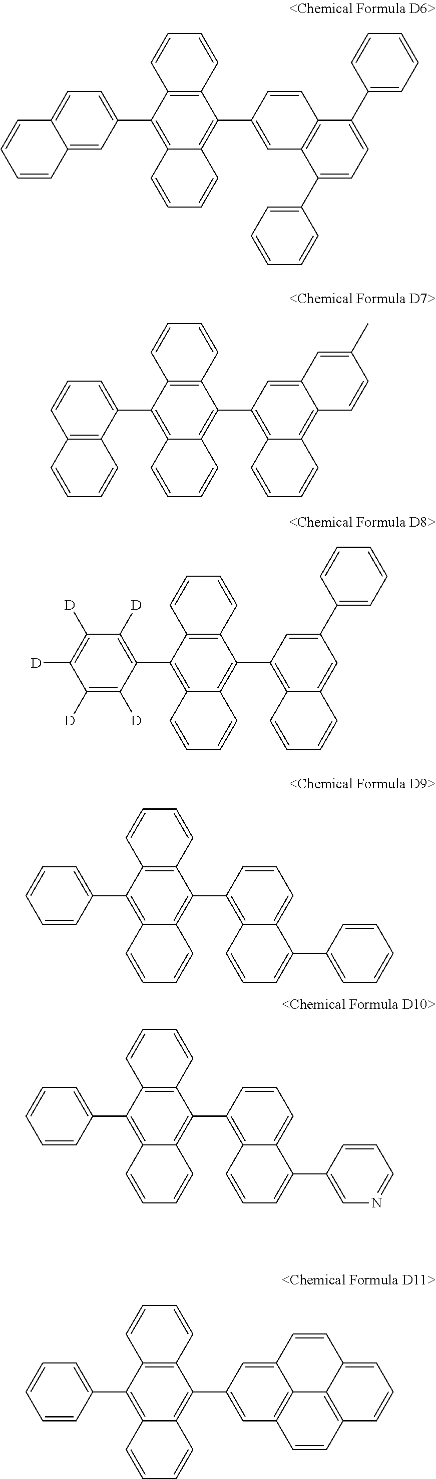

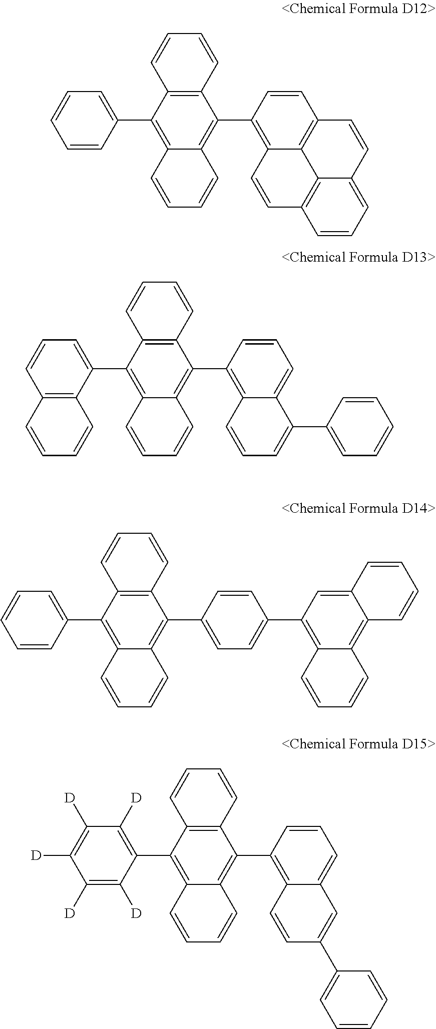

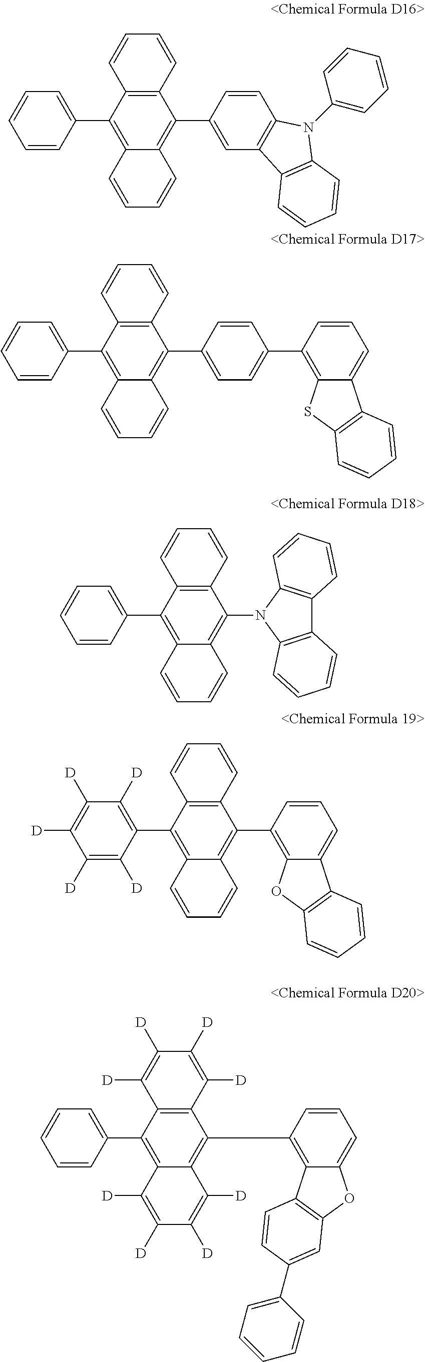

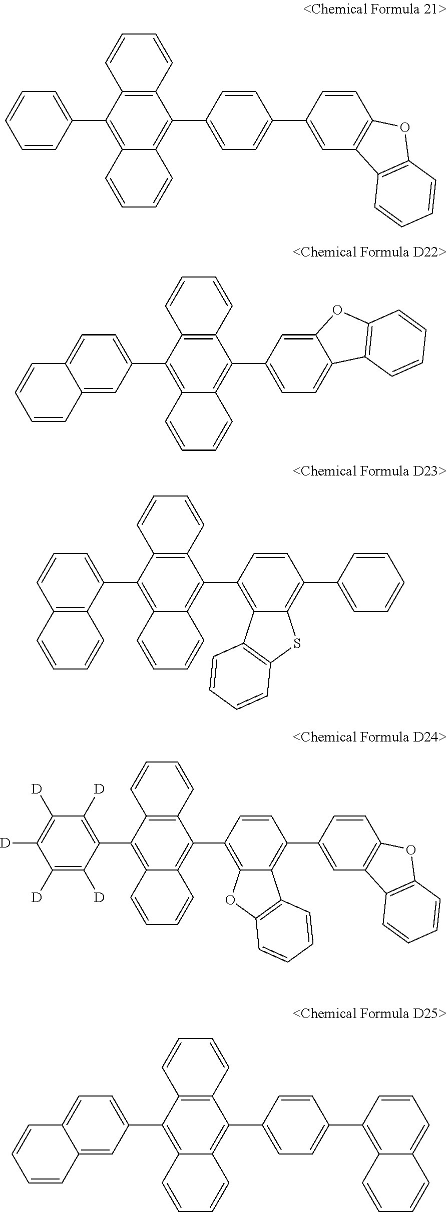

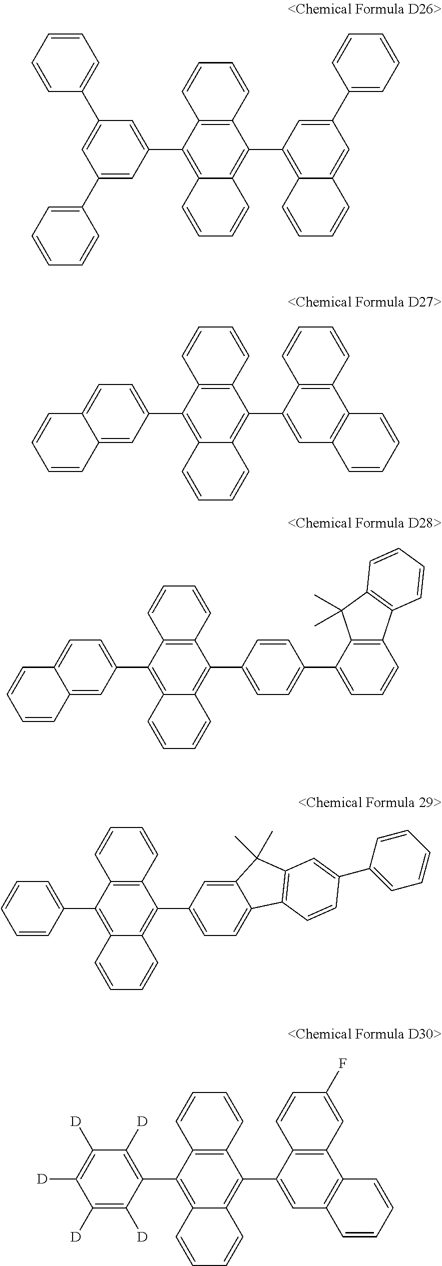

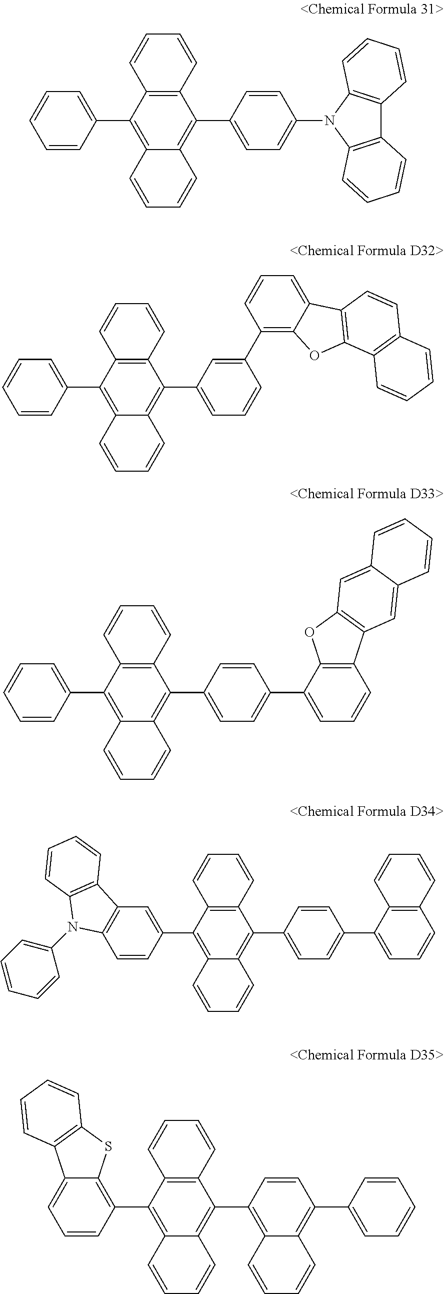 [SMILES: c1ccc(-c2c3ccccc3c(-c3ccc(-n4c5ccccc5c5ccccc54)cc3)c3ccccc23)cc1 ; c1ccc(-c2c3ccccc3c(-c3cccc(-c4cccc5c4oc4c6ccccc6ccc54)c3)c3ccccc23)cc1 ; c1ccc(-c2c3ccccc3c(-c3ccc(-c4cccc5c4oc4cc6ccccc6cc45)cc3)c3ccccc23)cc1 ; c1ccc(-n2c3ccccc3c3cc(-c4c5ccccc5c(-c5ccc(-c6cccc7ccccc67)cc5)c5ccccc45)ccc32)cc1 ; c1ccc(-c2ccc(-c3c4ccccc4c(-c4cccc5c4sc4ccccc45)c4ccccc34)c3ccccc23)cc1]

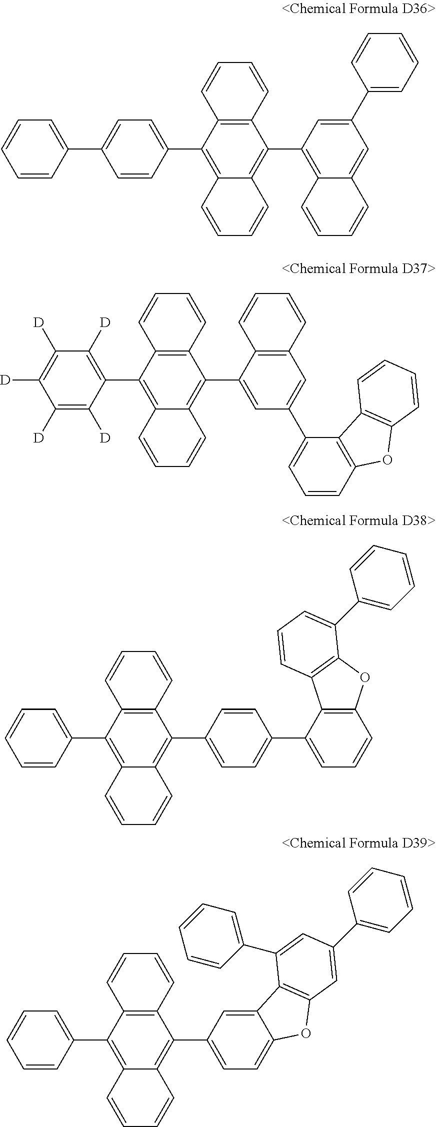

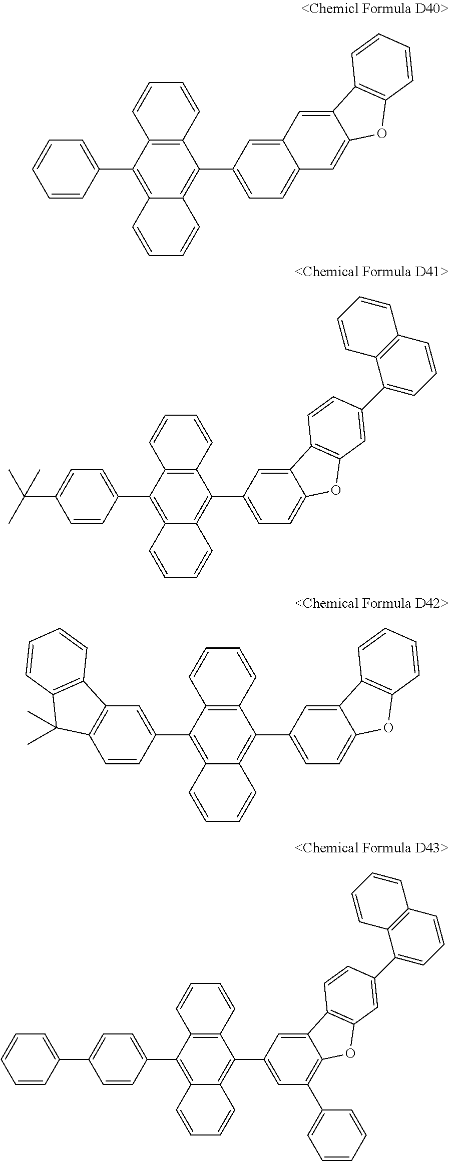 [SMILES: c1ccc(-c2c3ccccc3c(-c3ccc4cc5oc6ccccc6c5cc4c3)c3ccccc23)cc1 ; CC(C)(C)c1ccc(-c2c3ccccc3c(-c3ccc4oc5cc(-c6cccc7ccccc67)ccc5c4c3)c3ccccc23)cc1 ; CC1(C)c2ccccc2-c2cc(-c3c4ccccc4c(-c4ccc5oc6ccccc6c5c4)c4ccccc34)ccc21 ; c1ccc(-c2ccc(-c3c4ccccc4c(-c4cc(-c5ccccc5)c5oc6cc(-c7cccc8ccccc78)ccc6c5c4)c4ccccc34)cc2)cc1]

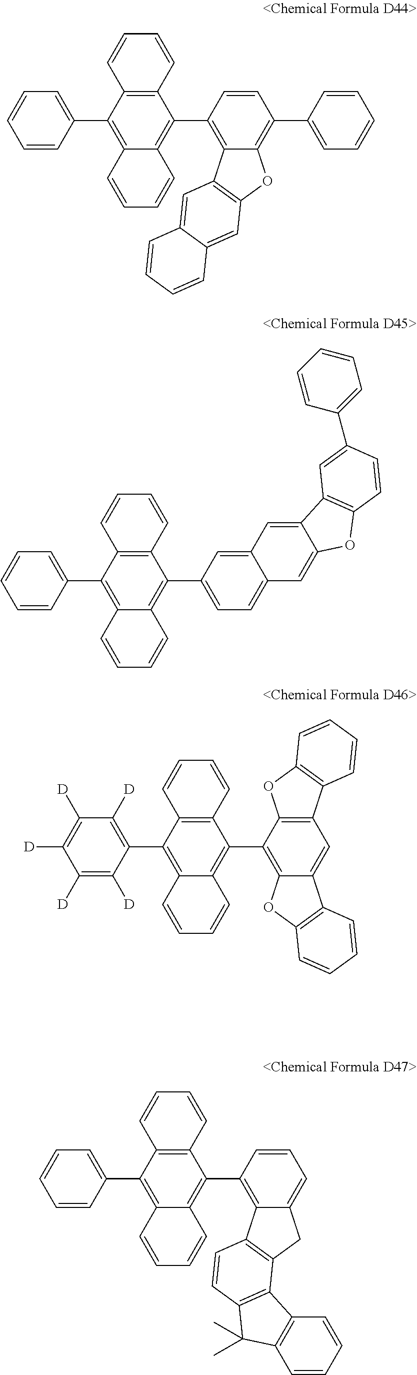

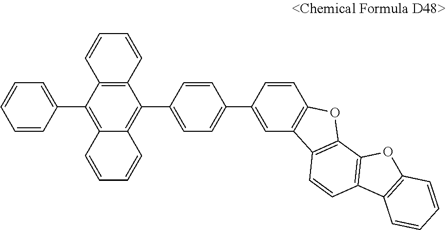 [SMILES: c1ccc(-c2c3ccccc3c(-c3ccc(-c4ccc5oc6c(ccc7c8ccccc8oc76)c5c4)cc3)c3ccccc23)cc1]

According to a more preferable embodiment thereof, the present disclosure provides a method for fabricating an organic light-emitting diode, the method including the steps of: forming an anode as a first electrode; a forming a light-emitting layer on the anode; and forming a cathode as a second electrode facing the first electrode on the light-emitting layer, wherein the light-emitting layer is formed by co-depositing a host material and a dopant material, the dopant material being at least one of the compounds with a substituent represented by Structural Formula A. According to the structural feature of the compound with a substituent represented by Structural Formula A, the method for fabricating an organic light-emitting diode of the present disclosure can perform a deposition process at a low deposition temperature, whereby a deposition material for formation of a light-emitting layer is not thermally decomposed.

In this regard, at least one of the compounds represented by Chemical Formula D may be co-deposited as a host within the light-emitting layer to fabricate an organic light-emitting diode.

The content of the dopant in the light-emitting layer may range from about 0.01 to 20 parts by weight, based on 100 parts by weight of the host, but is not limited thereto.

In addition to the above-mentioned dopants and hosts, the light-emitting layer may further include various hosts and dopant materials.

Also, the present disclosure provides a polycyclic compound represented by Chemical Formula A or B. As stated above, the polycyclic compound represented by Chemical Formula A or B accounts for a dopant available as an organic light-emitting diode. When applied to the fabrication of an organic light-emitting diode, the polycyclic compound represented by Chemical Formula A or B can lower the deposition temperature, compared with a polycyclic compound with a hydrogen atom instead of the substituent T in Structural Formula A.

In addition, the present disclosure provides an organic light-emitting diode employing a polycyclic ring compound represented by Chemical Formula A or B.

Below, the method for fabricating an organic light-emitting diode according to an embodiment of the present disclosure is explained with reference to the drawing.

The FIGURE is a schematic cross-sectional view of the structure of an organic light-emitting diode according to an embodiment of the present disclosure.

As shown in the FIGURE, the organic light-emitting diode according to an embodiment of the present disclosure comprises an anode 20, a hole transport layer 40, an organic light-emitting layer 50 containing a host and a dopant, an electron transport layer 60, and a cathode 80, wherein the anode and the cathode serve as a first electrode and a second electrode, respectively, with the interposition of the hole transport layer between the anode and the light-emitting layer, and the electron transport layer between the light-emitting layer and the cathode.

Furthermore, the organic light-emitting diode according to an embodiment of the present disclosure may include a hole injection layer 30 between the anode 20 and the hole transport layer 40, and an electron injection layer 70 between the electron transport layer 60 and the cathode 80.

Reference is made to the FIGURE with regard to the organic light-emitting diode of the present disclosure and the fabrication thereof.

First, a substrate 10 is coated with an anode electrode material to form an anode 20. So long as it is used in a typical organic electroluminescence device, any substrate may be used as the substrate 10. Preferable is an organic substrate or transparent plastic substrate that exhibits excellent transparency, surface smoothness, ease of handling, and waterproofness. As the anode material, indium tin oxide (ITO), indium zinc oxide (IZO), tin oxide (SnO₂), or zinc oxide (ZnO), which are transparent and superior in terms of conductivity, may be used.

A hole injection layer material is applied on the anode 20 by thermal deposition in a vacuum or by spin coating to form a hole injection layer 30. Subsequently, thermal deposition in a vacuum or by spin coating may also be conducted to form a hole transport layer 40 with a hole transport layer material on the hole injection layer 30.

So long as it is typically used in the art, any material may be selected for the hole injection layer without particular limitations thereto. Examples include, but are not limited to, 2-TNATA [4,4′,4″-tris(2-naphthylphenyl-phenylamino)-triphenylamine], NPD[N,N′-di(1-naphthyl)-N,N′-diphenylbenzidine)], TPD[N,N′-diphenyl-N,N′-bis(3-methylphenyl)-1,1′-biphenyl-4,4′-diamine], and DNTPD[N,N′-diphenyl-N,N′-bis-[4-(phenyl-m-tolyl-amino)-phenyl]-biphenyl-4,4′-diamine].

Any material that is typically used in the art may be selected for the hole transport layer without particular limitations thereto. Examples include, but are not limited to, N,N′-bis(3-methylphenyl)-N,N′-diphenyl-[1,1-biphenyl]-4,4′-diamine (TPD) and N,N′-di(naphthalen-1-yl)-N,N′-diphenylbenzidine (a-NPD).

In an embodiment of the present disclosure, an electron blocking layer may be additionally disposed on the hole transport layer. Functioning to prevent the electrons injected from the electron injection layer from entering the hole transport layer from the light-emitting layer, the electron blocking layer is adapted to increase the life span and luminous efficiency of the diode. The electron blocking layer may be formed of a well-known material or a combination of well-known materials, as necessary, at a suitable position between the light-emitting layer and the hole injection layer. Particularly, the electron blocking layer may be formed between the light-emitting layer and the hole transport layer.

Next, the light-emitting layer 50 may be deposited on the hole transport layer 40 or the electron blocking layer by deposition in a vacuum or by spin coating.

Herein, the light-emitting layer may contain a host and a dopant and the materials are as described above.

In some embodiments of the present disclosure, the light-emitting layer particularly ranges in thickness from 50 to 2,000 Å.

Meanwhile, the electron transport layer 60 is applied on the light-emitting layer by deposition in a vacuum and spin coating.

A material for use in the electron transport layer functions to stably carry the electrons injected from the electron injection electrode (cathode), and may be an electron transport material known in the art. Examples of the electron transport material known in the art include quinoline derivatives, particularly, tris(8-quinolinolate)aluminum (Alq₃), Liq, TAZ, BAlq, beryllium bis(benzoquinolin-10-olate) (Bebq2), Compound 201, Compound 202, BCP, and oxadiazole derivatives such as PBD, BMD, and BND, but are not limited thereto.

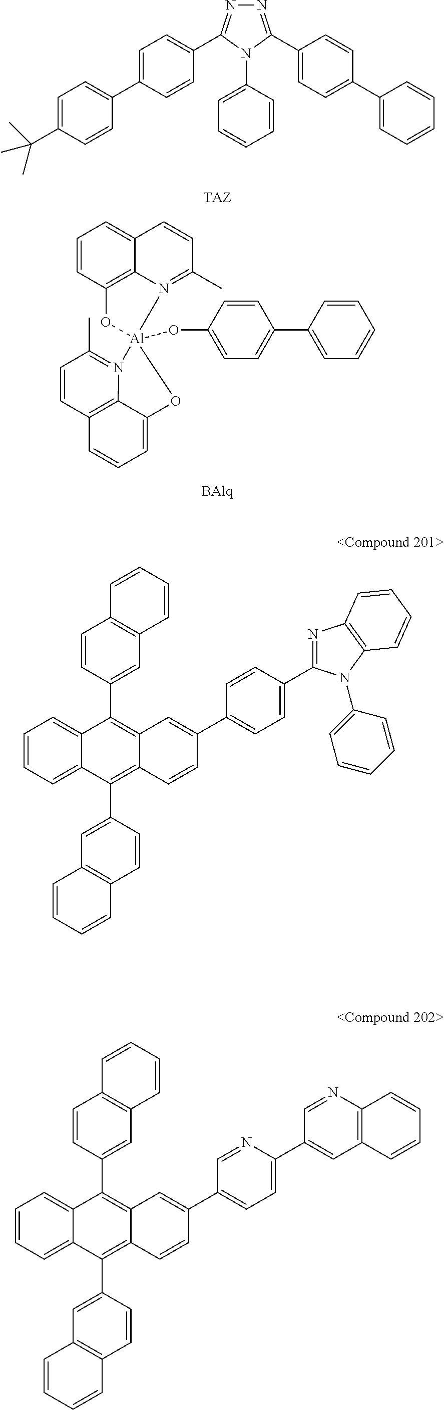

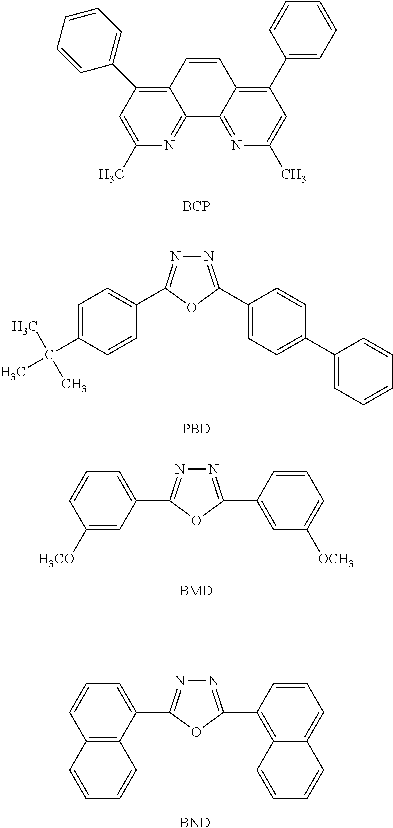

In the organic light-emitting diode of the present disclosure, an electron injection layer (EIL) that functions to facilitate electron injection from the cathode may be deposited on the electron transport layer. The material for the EIL is not particularly limited.

Any material that is conventionally used in the art can be available for the electron injection layer without particular limitations. Examples include CsF, NaF, LiF, Li₂O, and BaO.

Deposition conditions for the electron injection layer may vary, depending on compounds used, but may be generally selected from condition scopes that are almost the same as for the formation of hole injection layers.

The electron injection layer may range in thickness from about 1 Å to about 100 Å, and particularly from about 3 Å to about 90 Å. Given the thickness range for the electron injection layer, the diode can exhibit satisfactory electron injection properties without actually elevating a driving voltage.

In order to facilitate electron injection, the cathode may be made of a material having a small work function, such as metal or metal alloy such as lithium (Li), magnesium (Mg), calcium (Ca), an alloy aluminum (Al) thereof, aluminum-lithium (Al—Li), magnesium-indium (Mg—In), and magnesium-silver (Mg—Ag). Alternatively, ITO or IZO may be employed to form a transparent cathode for an organic light-emitting diode.

Moreover, the organic light-emitting diode of the present disclosure may further comprise a light-emitting layer containing a blue, green, or red luminescent material that emits radiations in the wavelength range of 380 nm to 800 nm. That is, the light-emitting layer in the present disclosure has a multi-layer structure wherein the blue, green, or red luminescent material may be a fluorescent material or a phosphorescent material.

Furthermore, at least one selected from among the layers may be deposited using a single-molecule deposition process or a solution process.

Here, the deposition process is a process by which a material is vaporized in a vacuum or at a low pressure and deposited to form a layer, and the solution process is a method in which a material is dissolved in a solvent and applied for the formation of a thin film by means of inkjet printing, roll-to-roll coating, screen printing, spray coating, dip coating, spin coating, etc.

Also, the organic light-emitting diode of the present disclosure may be applied to a device selected from among flat display devices, flexible display devices, monochrome or grayscale flat illumination devices, and monochrome or grayscale flexible illumination devices.

A better understanding of the present disclosure may be obtained through the following examples which are set forth to illustrate, but are not to be construed as limiting the present invention

### EXAMPLES

### Dopant Synthesis Example 1: Synthesis of [BD-1]

### Synthesis Example 1-1: Synthesis of A-1

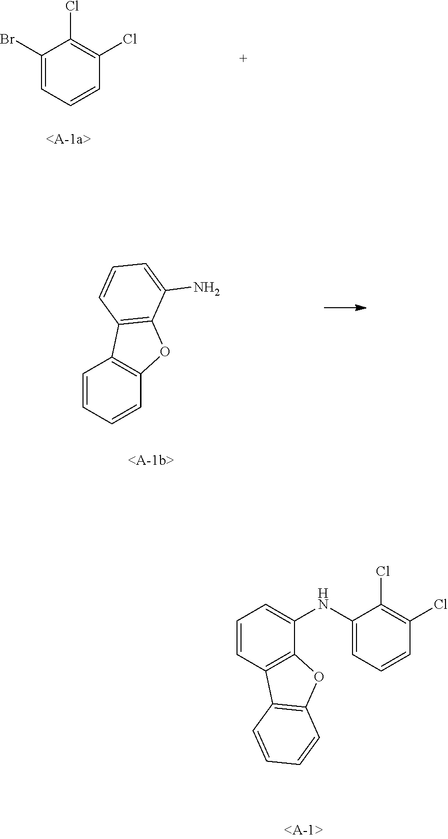 [SMILES: Clc1cccc(Br)c1Cl ; Nc1cccc2c1oc1ccccc12 ; Clc1cccc(Nc2cccc3c2oc2ccccc23)c1Cl]

In a reactor, <A-1a> (50 g), <A-1b> (42.6 g), tris(dibenzylideneacetone)dipalladium(0) (4.1 g), sodium tert-butoxide (42.6 g), bis(diphenylphosphino)-1,1′-binaphthyl (2.8 g), and toluene (600 mL) were stirred together for 5 hours under reflux. The reaction mixture was cooled to room temperature and added with ethyl acetate and water to separate an organic layer. Purification by silica gel chromatography afforded <A-1>. (58.5 g, 80.5%)

### Synthesis Example 1-2: Synthesis of A-2

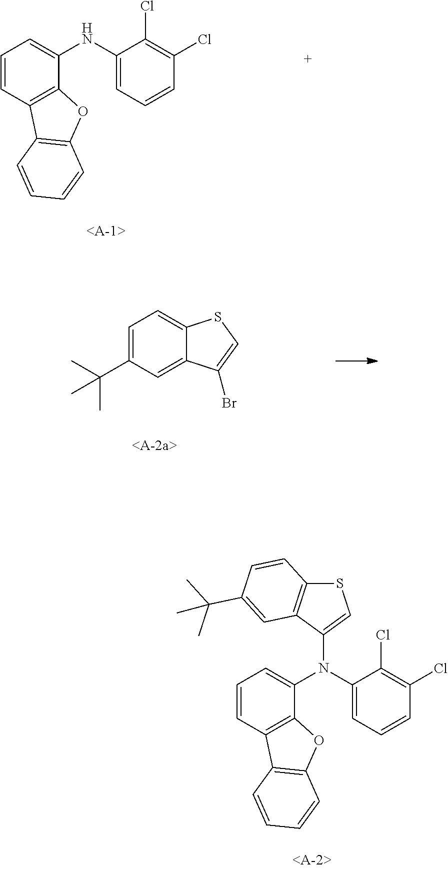 [SMILES: Clc1cccc(Nc2cccc3c2oc2ccccc23)c1Cl ; CC(C)(C)c1ccc2scc(Br)c2c1 ; CC(C)(C)c1ccc2scc(N(c3cccc(Cl)c3Cl)c3cccc4c3oc3ccccc34)c2c1]

In a reactor, <A-1> (50 g), <A-2a> (41 g), bis(tri-tert-butylphosphine)palladium(0) (1.6 g), sodium tert-butoxide (29.3 g), and toluene (600 mL) were stirred together for 16 hours under reflux. The reaction mixture was cooled to room temperature and then added with ethyl acetate and water to separate an organic layer. Purification by silica gel chromatography afforded <A-2>. (49.2 g, 62.5%)

### Synthesis Example 1-3 Synthesis of A-3

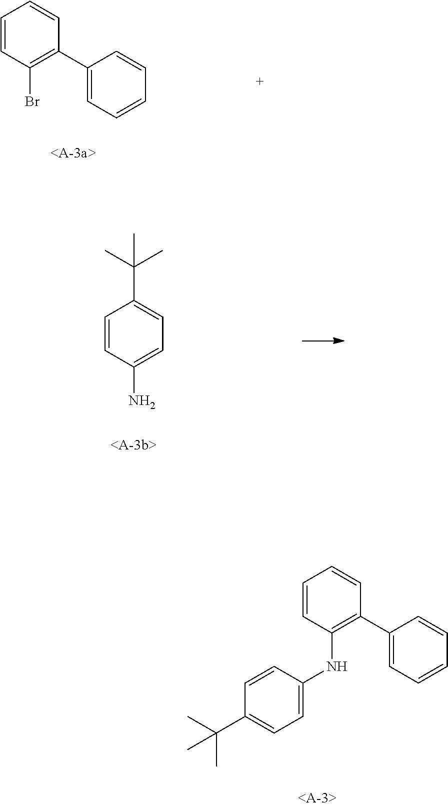 [SMILES: Brc1ccccc1-c1ccccc1 ; CC(C)(C)c1ccc(N)cc1 ; CC(C)(C)c1ccc(Nc2ccccc2-c2ccccc2)cc1]

In a reactor, <A-3a> (50 g), <A-3b> (33.6 g), tris(dibenzylideneacetone)dipalladium(0) (3.9 g), bis(diphenylphosphino)-1,1′-binaphthyl (2.7 g), sodium tert-butoxide (41.2 g), and toluene (500 mL) were stirred together for 16 hours under reflux. The reaction mixture was cooled to room temperature and then added with ethyl acetate and water to separate an organic layer. Purification by silica gel chromatography afforded <A-3>. (54 g, 83.5%)

### Synthesis Example 1-4 Synthesis of A-4

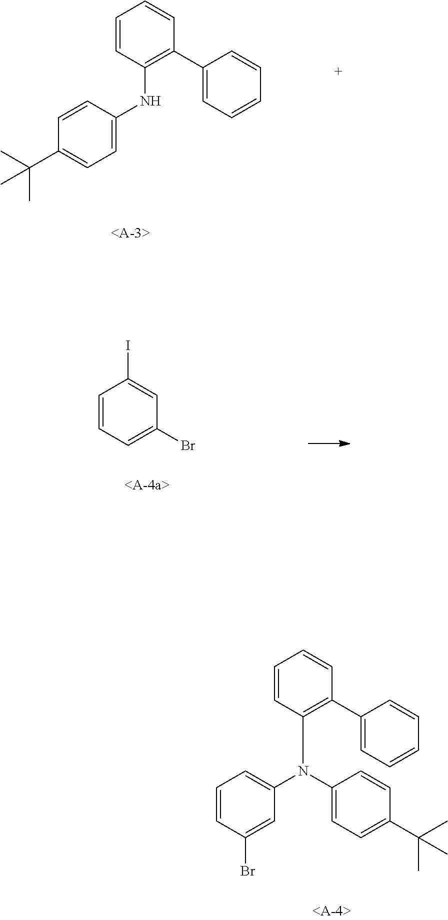 [SMILES: CC(C)(C)c1ccc(Nc2ccccc2-c2ccccc2)cc1 ; Brc1cccc(I)c1 ; CC(C)(C)c1ccc(N(c2cccc(Br)c2)c2ccccc2-c2ccccc2)cc1]

In a reactor, <A-3> (40 g), <A-4a> (39.4 g), palladium (II) acetate (0.3 g), xantphos (0.8 g), sodium tert-butoxide (19.2 g) and toluene (500 mL) were stirred together for 16 hours under reflux. The reaction mixture was cooled to room temperature and then added with ethyl acetate and water to separate an organic layer. Purification by silica gel chromatography afforded <A-4>. (27.5 g, 45.4%)

### Synthesis Example 1-5 Synthesis of A-5

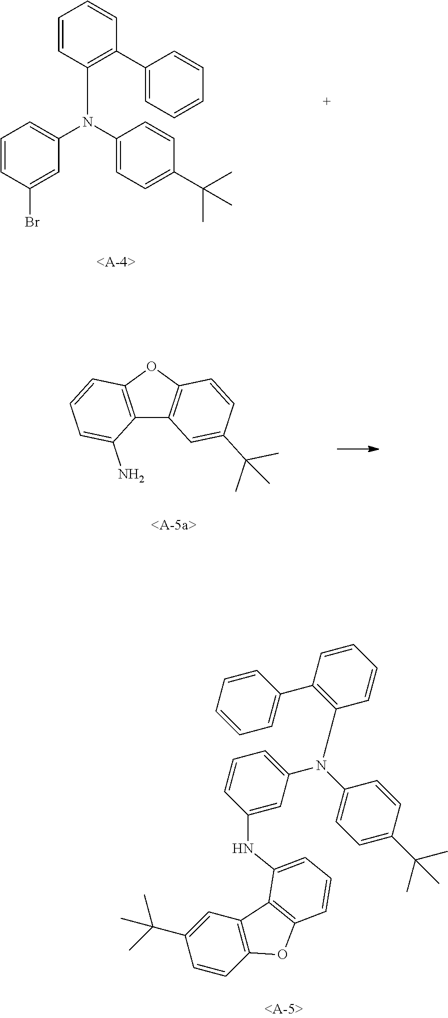 [SMILES: CC(C)(C)c1ccc(N(c2cccc(Br)c2)c2ccccc2-c2ccccc2)cc1 ; CC(C)(C)c1ccc2oc3cccc(N)c3c2c1 ; CC(C)(C)c1ccc(N(c2cccc(Nc3cccc4oc5ccc(C(C)(C)C)cc5c34)c2)c2ccccc2-c2ccccc2)cc1]

The same procedure as in Synthesis Example 1-3 was carried out, with the exception of using <A-4> and <A-5a> instead of <A-3a> and <A-3b>, respectively, to afford <A-5>. (yield 88.2%)

### Synthesis Example 1-6 Synthesis of A-6

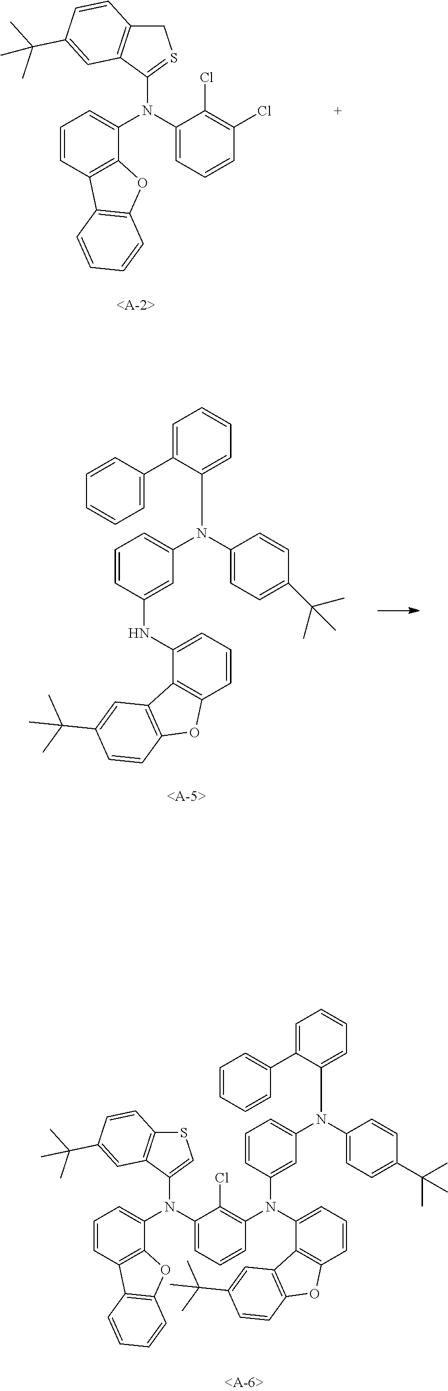

The same procedure as in Synthesis Example 1-2 was carried out, with the exception of using <A-5> and <A-2> instead of <A-1> and <A-2a>, respectively, to afford <A-6>. (yield 79.2%)

### Synthesis Example 1-7: Synthesis of [BD-1]

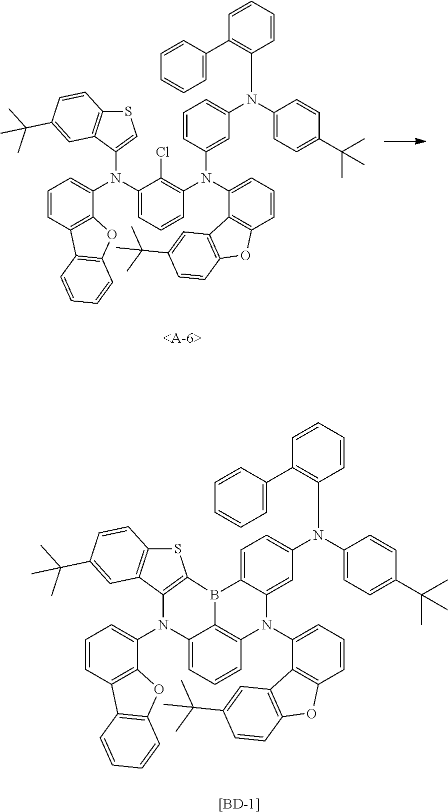

In a reactor, a mixture of <A-6> (30 g) and tert-butyl benzene (200 mL) was added with drops of 2M tert-butyl lithium pentane (48 mL) at −78° C. After the temperature was elevated to 60° C., the resulting mixture was stirred for 2 hours, and nitrogen gas was introduced to completely remove the pentane. The temperature was lowered again to −78° C. before adding drops of boron tribromide (8 mL). The temperature was elevated to room temperature, followed by stirring for 2 hours. At 0° C., N,N-diisopropylethylamine (14 mL) was dropwise added. The temperature was elevated again to 120° C. before stirring for 16 hours. The reaction mixture was cooled to room temperature and added with 10% aqueous sodium acetate solution and ethyl acetate to separate an organic layer. Purification by silica gel chromatography afforded [BD-1]. (3 g, 10.2%)
MS (MALDI-TOF): m/z 1067.47 [M⁺]

### Dopant Synthesis Example 2: Synthesis of [BD-2]

### Synthesis Example 2-1: Synthesis of B-1

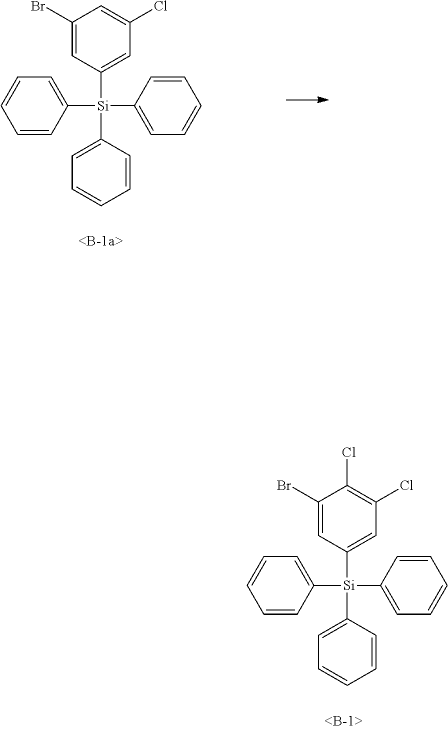 [SMILES: Clc1cc(Br)cc([Si](c2ccccc2)(c2ccccc2)c2ccccc2)c1 ; Clc1cc([Si](c2ccccc2)(c2ccccc2)c2ccccc2)cc(Br)c1Cl]

In a reactor, 2.0 M lithium diisopropylamide (140 mL) was dropwise added to a solution of <B-1a> (50 g) in tetrahydrofuran (50 mL) at −78° C. At the same temperature, stirring was conducted for 3 hours, followed by slowing adding hexachloroethane. After the temperature was elevated to room temperature, the mixture was stirred for 16 hours. Ethyl acetate and water were added to separate an organic layer. Purification by silica gel chromatography afforded <B-1>. (42.5 g, 78.9%)

### Synthesis Example 2-2 Synthesis of B-2

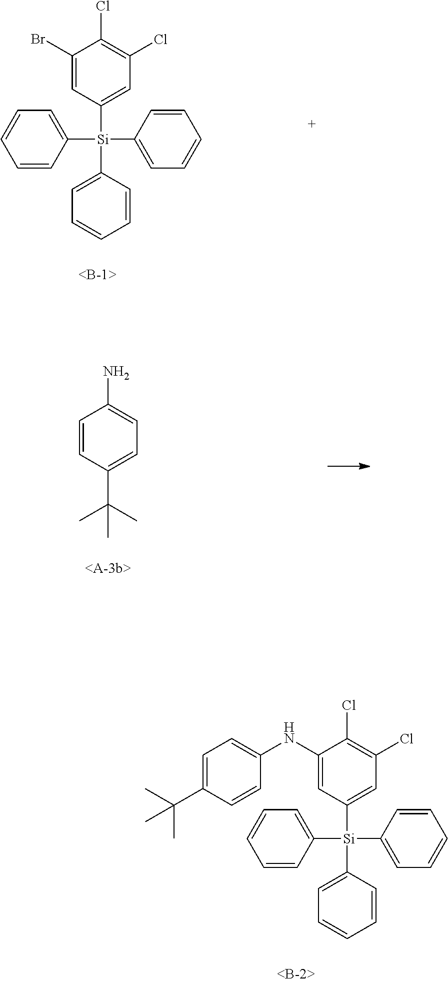 [SMILES: Clc1cc([Si](c2ccccc2)(c2ccccc2)c2ccccc2)cc(Br)c1Cl ; CC(C)(C)c1ccc(N)cc1 ; CC(C)(C)c1ccc(Nc2cc([Si](c3ccccc3)(c3ccccc3)c3ccccc3)cc(Cl)c2Cl)cc1]

The same procedure as in Synthesis Example 1-3 was carried out, with the exception of using <B-1> instead of <A-3a>, to afford <B-2>. (yield 56%)

### Synthesis Example 2-3 Synthesis of B-3

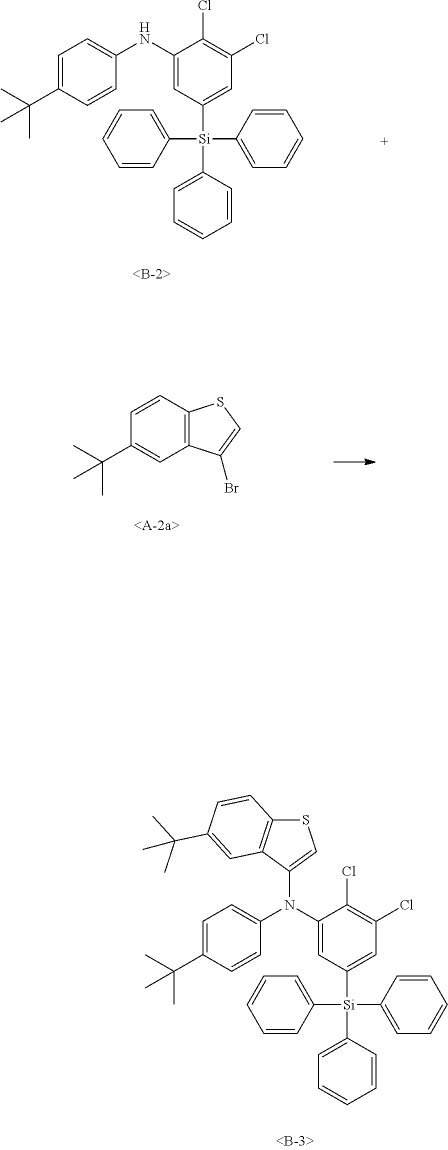 [SMILES: CC(C)(C)c1ccc(Nc2cc([Si](c3ccccc3)(c3ccccc3)c3ccccc3)cc(Cl)c2Cl)cc1 ; CC(C)(C)c1ccc2scc(Br)c2c1 ; CC(C)(C)c1ccc(N(c2cc([Si](c3ccccc3)(c3ccccc3)c3ccccc3)cc(Cl)c2Cl)c2csc3ccc(C(C)(C)C)cc23)cc1]

The same procedure as in Synthesis Example 1-2 was carried out, with the exception of using <B-2> instead of <A-1>, to afford <B-3>. (yield 97.5%)

### Synthesis Example 2-4 Synthesis of B-4

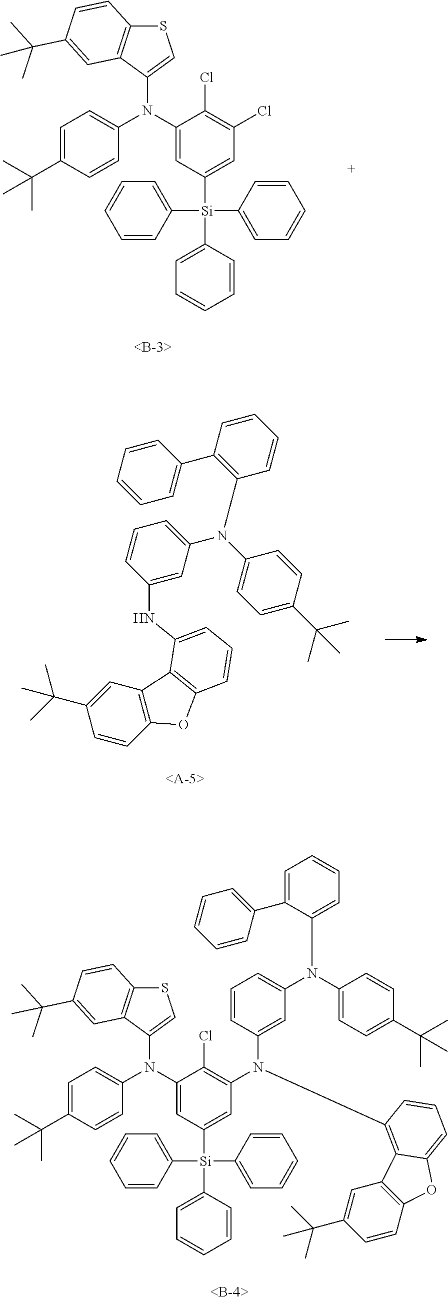

The same procedure as in Synthesis Example 1-2 was carried out, with the exception of using <A-5> and <B-3> instead of <A-1> and <A-2a>, respectively, to afford <B-4>. (yield 82.4%)

### Synthesis Example 2-5 Synthesis of [BD-2]

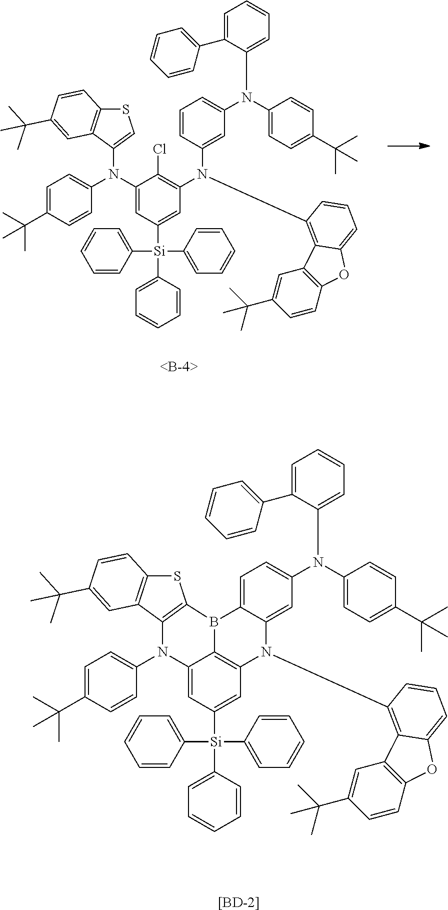

The same procedure as in Synthesis Example 1-7 was carried out, with the exception of using <B-4> instead of <A-6>, to afford [BD-2]. (yield 9.7%)
MS (MALDI-TOF): m/z 1291.60 [M⁺]

### Examples 1 and 2: Fabrication of Organic Light-Emitting Diodes and Evaluation

An ITO glass substrate was patterned to have a translucent area of 2 mm×2 mm and cleansed. The ITO glass was mounted in a vacuum chamber that was then set to have a base pressure of 1×10⁻⁷ torr. On the ITO glass substrate, a hole injection layer (100 Å) was formed by depositing the electron acceptor of the following Structural Formula [Acceptor-1] and [Chemical Formula F] at a ratio of [Acceptor-1]: [Chemical Formula F]=2: 98. Then, [Chemical Formula F] was deposited to form a film (550 Å) as a hole transport layer. Subsequently, [Chemical Formula G] was deposited to form a film (50 Å) as an electron blocking layer. Thereafter, a light-emitting layer (200 Å) was formed of a combination of [BH-1] as a host and the compound (2 wt %) of the present disclosure as a dopant. Then, [Chemical Formula E-1] and [Chemical Formula E-2] were deposited at a weight ratio of 1:1 to form an electron transport layer (300 Å) on which an electron injection layer of [Chemical Formula E-2] (10 Å) was formed and then covered with an Al layer (1000 Å) to fabricate an organic light-emitting diode. The organic light-emitting diodes thus obtained were measured at 0.4 mA for luminescence properties:

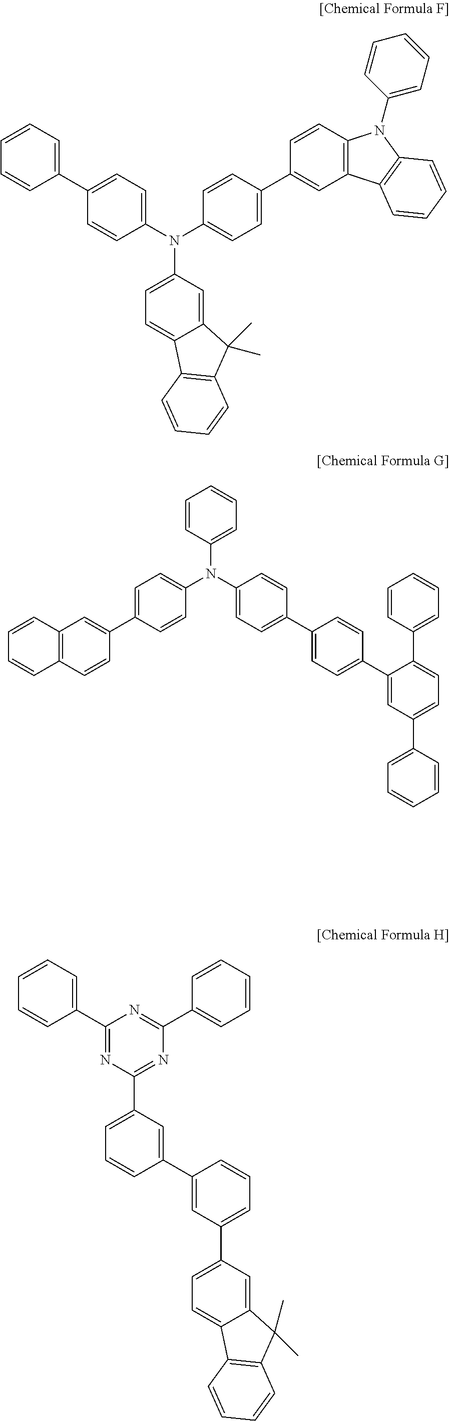 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccccc3)c(-c3ccc(-c4ccc(N(c5ccccc5)c5ccc(-c6ccc7ccccc7c6)cc5)cc4)cc3)c2)cc1 ; CC1(C)c2ccccc2-c2ccc(-c3cccc(-c4cccc(-c5nc(-c6ccccc6)nc(-c6ccccc6)n5)c4)c3)cc21]

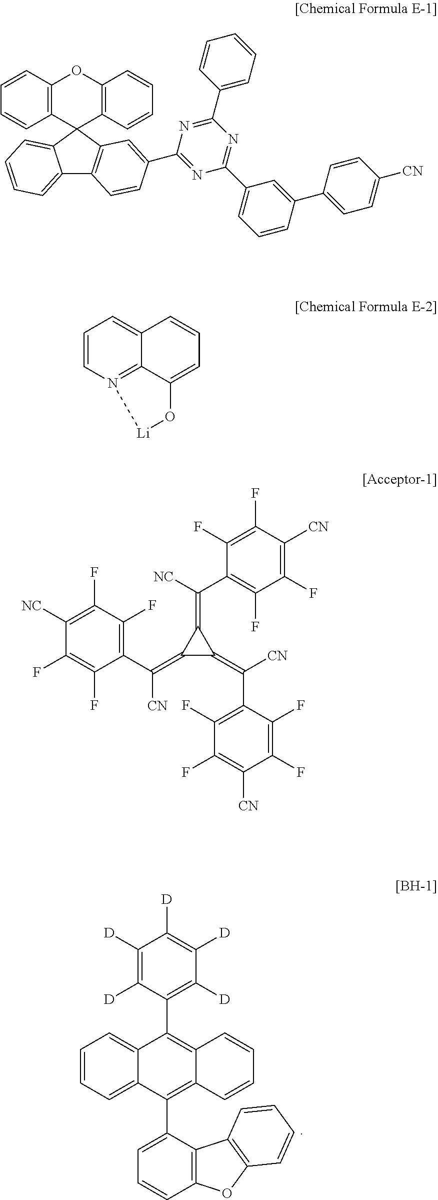

### Comparative Examples 1 and 2

Organic light-emitting diodes were fabricated in the same manner as in Examples, with the exception of using the following [RD-1] to [RD-2], instead of the dopant compounds of the Examples, for the light-emitting layers. The organic light-emitting diodes were measured for emission properties at 0.4 mA. Structures of [RD-1] and [RD-2] are as follows.

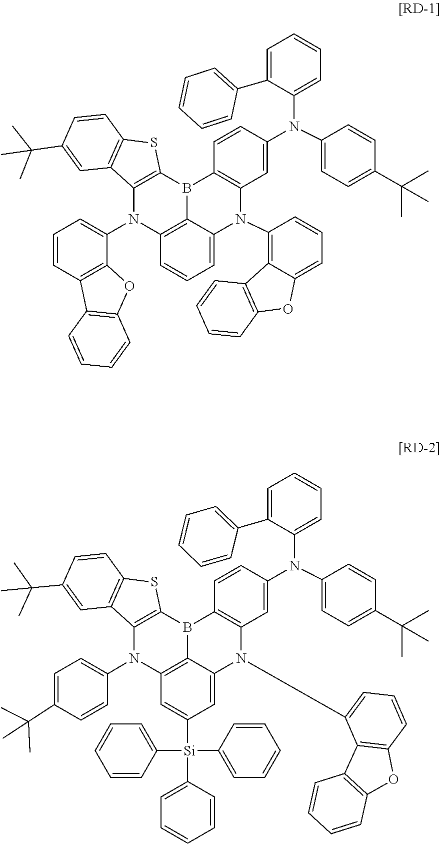

The organic light-emitting diodes fabricated in Examples 1 to 2 and Comparative Examples 1 and 2 were measured for external quantum efficiency, life time, and deposition temperature, and the measurements are summarized in Table 1, below.

TABLE 1

| | | | External | | |
|---|---|---|---|---|---|
| | | Driving | Quantum | | Deposition |
| | | Volt. | Efficiency | Life time | Temp. |
| | Dopant | (V) | (EQE, %) | (T97, hr) | (° C.) |
| Ex. 1 | BD-1 | 3.4 | 10.6 | 243 | 165 |
| Ex. 2 | BD-2 | 3.3 | 11.4 | 234 | 174 |
| C. Ex. 1 | RD-1 | 3.4 | 10.5 | 240 | 195 |
| C. Ex. 2 | RD-1 | 3.3 | 11.2 | 228 | 195 |

As is understood from the date of Table 1, the organic light-emitting diodes fabricated with the use of the organic compound possessing a substituent represented by Structural Formula A were observed to allow the deposition to be carried out at a temperature more than 20° C. lower than the organic light-emitting diodes employing the compounds of Comparative Examples, which do not possess the substituent represented by Structural Formula A while exhibiting equivalent or similar levels of external quantum efficiency and life span properties.

Organic compounds used in OLEDs are apt to be damaged and thermally decomposed when they stay for a long period of time within the crucible given a high decomposition temperature. Thus, the deposition temperature is preferably set to be as low as possible. When subjected to deposition processes, the organic compounds according to the present disclosure meet the requirements, thus offering many advantages for the fabrication of organic light-emitting diodes.

1. A method for fabricating an organic light-emitting diode, the method comprising the steps of:
forming a first electrode;
forming an organic layer on the first electrode; and
forming a second electrode on the organic layer,
wherein the organic layer is formed by depositing a compound for organic light-emitting diodes, the compound possessing at least one substituent represented by Structural Formula A within the molecule thereof and being deposited at a temperature more than 20° C. lower than a deposition temperature for a compound having hydrogen substituted for the substituent T in Structural Formula A when the depositing is carried out at 10⁻⁷ torr or less: 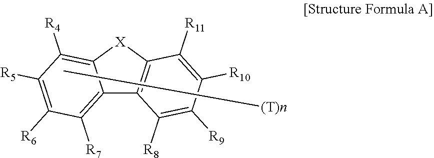
wherein,
X is O or S,
one of R₄ to R₁₁ is a single bond for bonding to an intramolecular portion other than the substituent represented by Structural Formula A in the compound for organic light-emitting diodes,
n radicals of R₄ to R₁₁ are represented by substituent (T)n, each T being a substituted or unsubstituted alkyl of 1 to 10 carbon atoms,
n is an integer of 1 to 3, wherein when n is 2 or higher, the corresponding T's are same or different, and
radicals of R₄ to R₁₁ other than the single bond or T are same or different and are each independently any one selected from a hydrogen atom, a deuterium atom, a substituted or unsubstituted aryl of 6 to 18 carbon atoms, and a substituted or unsubstituted alkyl of 1 to 10 carbon atoms,
wherein the term “substituted” in the expression “substituted or unsubstituted” used for compounds of Chemical Formula A means having at least one substituent selected from the group consisting of a deuterium atom, a cyano, a halogen, a hydroxy, a nitro, an alkyl of 1 to 24 carbon atoms, a halogenated alkyl of 1 to 24 carbon atoms, a cycloalkyl of 3 to 30 carbon atoms, an alkenyl of 2 to 24 carbon atoms, an alkynyl of 2 to 24 carbon atoms, a heteroalkyl of 1 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an aromatic hydrocarbon ring-fused cycloalkyl of 7 to 24 carbon atoms, a heteroaromatic ring-fused cycloalkyl of 5 to 24 carbon atoms, an aromatic hydrocarbon ring-fused heterocycloalkyl of 6 to 24 carbon atoms, an aliphatic hydrocarbon ring-fused aryl of 8 to 24 carbon atoms, an aliphatic hydrocarbon ring-fused heteroaryl of 5 to 24 carbon atoms, an alkoxy of 1 to 24 carbon atoms, an amine of 0 to 24 carbon atoms, a silyl of 0 to 24 carbon atoms, a germanium of 0 to 24 carbon atoms, an aryloxy of 6 to 24 carbon atoms, and an arylthiony of 6 to 24 carbon atoms, and at least one hydrogen atom on the substituent may be substituted by a deuterium atom.

2. The method for fabricating an organic light-emitting diode of claim 1, wherein the organic layer is any one selected from an electron injection layer, a hole injection layer, a hole transport layer, an electron blocking layer, a functional layer capable of both hole injection and hole transport, a light-emitting layer, an electron transport layer, an electron injection layer, a hole blocking layer, and a functional layer capable of both electron injection and electron transport

3. The method for fabricating an organic light-emitting diode of claim 2,
wherein the organic layer is a light-emitting layer, and
the light-emitting layer is composed of a host and a dopant, and the compound possessing a substituent represented by Structural Formula A is used as the dopant.

4. The method for fabricating an organic light-emitting diode of claim 1, wherein the compound possessing a substituent represented by Structural Formula A is a polycyclic compound represented by the following Chemical Formula A or B: 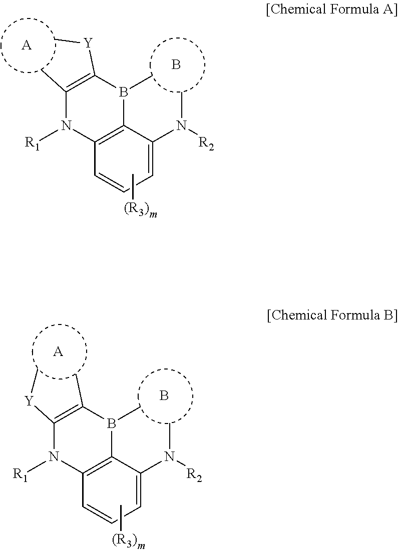
wherein,
A or B, which are same or different, are each independently a substituted or unsubstituted aromatic hydrocarbon ring of 6 to 30 carbon atoms, a substituted or unsubstituted heteroaromatic ring of 2 to 30 carbon atoms, a substituted or unsubstituted aliphatic hydrocarbon ring of 3 to 30 carbon atoms, a substituted or unsubstituted heteroaliphatic ring of 2 to 30 carbon atoms, a substituted or unsubstituted aromatic hydrocarbon ring-fused aliphatic hydrocarbon ring of 5 to 30 carbon atoms, and a substituted or unsubstituted aliphatic hydrocarbon ring-fused aromatic hydrocarbon ring of 5 to 30 carbon atoms,
Y is O or S,
R₃ is any one selected from a hydrogen atom, a deuterium atom, a substituted or unsubstituted alkyl of 1 to 30 carbon atoms, a substituted or unsubstituted alkenyl of 2 to 30 carbon atoms, a substituted or unsubstituted alkynyl of 2 to 20 carbon atoms, a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, a substituted or unsubstituted aliphatic hydrocarbon ring-fused heteroaryl of 5 to 30 carbon atoms, a substituted or unsubstituted alkoxy of 1 to 30 carbon atoms, a substituted or unsubstituted aryloxy of 6 to 30 carbon atoms, a substituted or unsubstituted cycloalkyloxy of 3 to 30 carbon atoms, a substituted or unsubstituted heteroaryloxy of 2 to 30 carbon atoms, a substituted or unsubstituted akylthio of 1 to 30 carbon atoms, a substituted or unsubstituted arylthio of 6 to 30 carbon atoms, a substituted or unsubstituted cycloalkylthio of 3 to 30 carbon atoms, a substituted or unsubstituted heteroarylthio of 2 to 30 carbon atoms, a substituted or unsubstituted amine of 0 to 30 carbon atoms, a substituted or unsubstituted silyl of 0 to 30 carbon atoms, a germanium of 0 to 30 carbon atoms, a nitro, a cyano, and a halogen,
m is 3, wherein the corresponding R₃'s are same or different,
R₁ and R₂, which are same or different, are each independently any one selected from a substituted or unsubstituted aryl of 6 to 50 carbon atoms, a substituted or unsubstituted cycloalkyl of 3 to 30 carbon atoms, a substituted or unsubstituted cycloalkenyl of 5 to 30 carbon atoms, a substituted or unsubstituted heterocycloalkyl of 2 to 30 carbon atoms, a substituted or unsubstituted heteroalkyl of 2 to 50 carbon atoms, a substituted or unsubstituted heteroaryl of 2 to 50 carbon atoms, a substituted or unsubstituted aromatic hydrocarbon ring-fused cycloalkyl of 7 to 30 carbon atoms, a substituted or unsubstituted heteroaromatic ring-fused cycloalkyl of 5 to 30 carbon atoms, a substituted or unsubstituted aromatic hydrocarbon ring-fused heterocycloalkyl of 6 to 30 carbon atoms, a substituted or unsubstituted aliphatic hydrocarbon ring-fused aryl of 8 to 30 carbon atoms, and a substituted or unsubstituted aliphatic hydrocarbon ring-fused heteroaryl of 5 to 30 carbon atoms,
at least one of R₁ and R₂ being a substituent represented by Structural Formula A,
wherein Chemical Formulas A and B, Structural Formula A, and the term “substituted” in the expression “substituted or unsubstituted” are as defined in claim 1.

5. The method for fabricating an organic light-emitting diode of claim 4, wherein R₂ in Chemical Formulas A and B is represented by Structural Formula A.

6. The method for fabricating an organic light-emitting diode of claim 4, wherein the A and B ring moieties in Chemical Formulas A and B are each independently a substituted or unsubstituted aromatic hydrocarbon ring of 6 to 20 carbon atoms.

7. The method for fabricating an organic light-emitting diode of claim 4, wherein n in Structural Formula is an integer of 1 or 2.

8. The method for fabricating an organic light-emitting diode of claim 4, wherein R₇ in Structural Formula A is a single bond to a nitrogen atom.

9. The method for fabricating an organic light-emitting diode of claim 4, wherein one or two of R₈ to R₁₁ in Structural Formula A are accounted for by substituent T.

10. The method for fabricating an organic light-emitting diode of claim 9, wherein R₉ in Structural Formula A is accounted for by substituent T.

11. The method for fabricating an organic light-emitting diode of claim 4, wherein T in Structural Formula is an alkyl of 3 to 10 carbon atoms with or without a deuterium atom or halogen atom as a substituent.

12. The method for fabricating an organic light-emitting diode of claim 4, wherein R₃ in Chemical Formulas A and B is a substituted or unsubstituted silyl of 1 to 30 carbon atoms.

13. The method for fabricating an organic light-emitting diode of claim 4, wherein the compound represented by Chemical Formula A or B has a molecular weight of 900 or higher.

14. The method for fabricating an organic light-emitting diode of claim 4, wherein the compound represented by Chemical Formula A or B is deposited at a temperature of 180° C. or less.

15. The method for fabricating an organic light-emitting diode of claim 4, wherein the compound represented by Chemical Formula A or B is any one selected from Compounds 1 to 18: 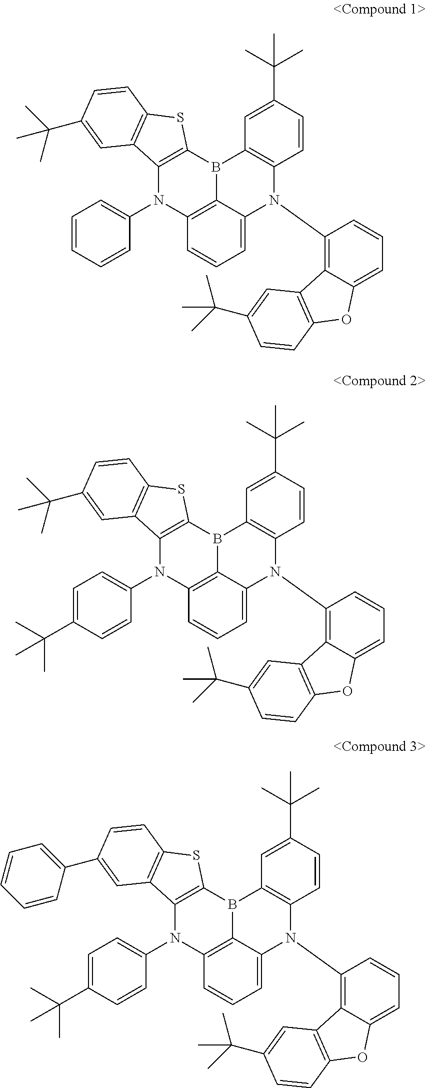 [SMILES: CC(C)(C)c1ccc2c(c1)B1c3sc4ccc(C(C)(C)C)cc4c3N(c3ccccc3)c3cccc(c31)N2c1cccc2oc3ccc(C(C)(C)C)cc3c12 ; CC(C)(C)c1ccc(N2c3cccc4c3B(c3cc(C(C)(C)C)ccc3N4c3cccc4oc5ccc(C(C)(C)C)cc5c34)c3sc4ccc(C(C)(C)C)cc4c32)cc1 ; CC(C)(C)c1ccc(N2c3cccc4c3B(c3cc(C(C)(C)C)ccc3N4c3cccc4oc5ccc(C(C)(C)C)cc5c34)c3sc4ccc(-c5ccccc5)cc4c32)cc1] 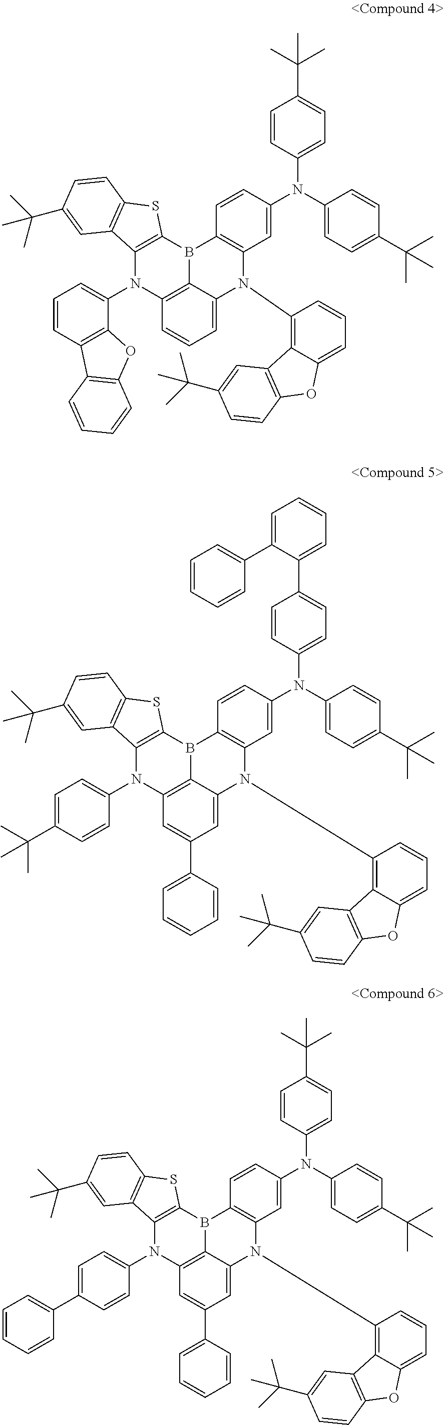 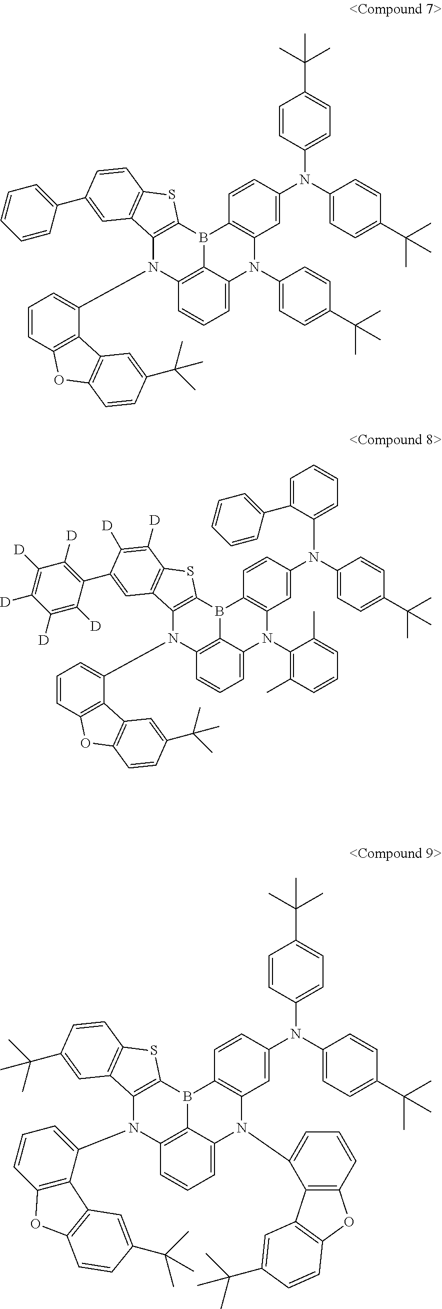 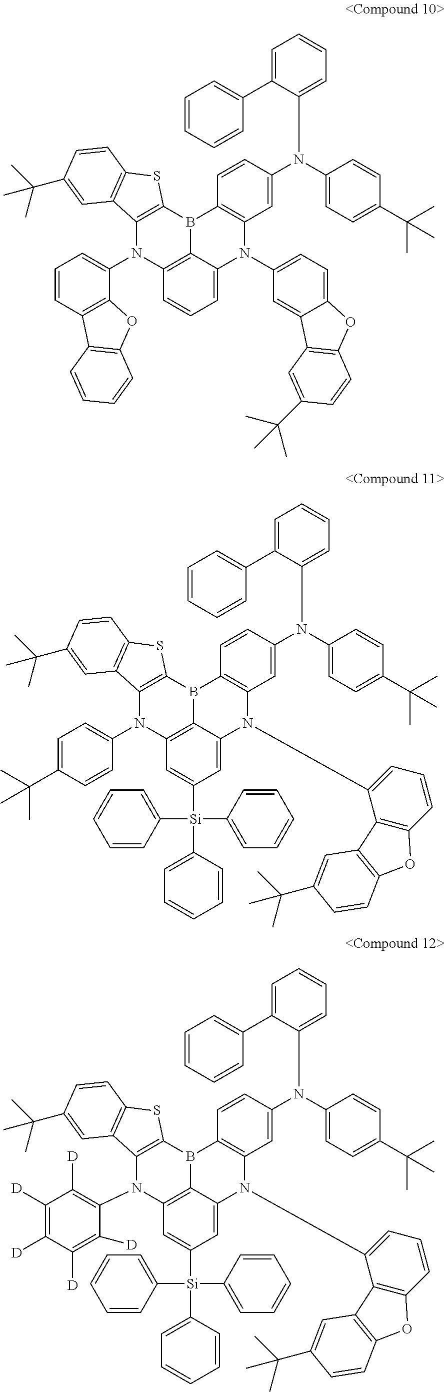 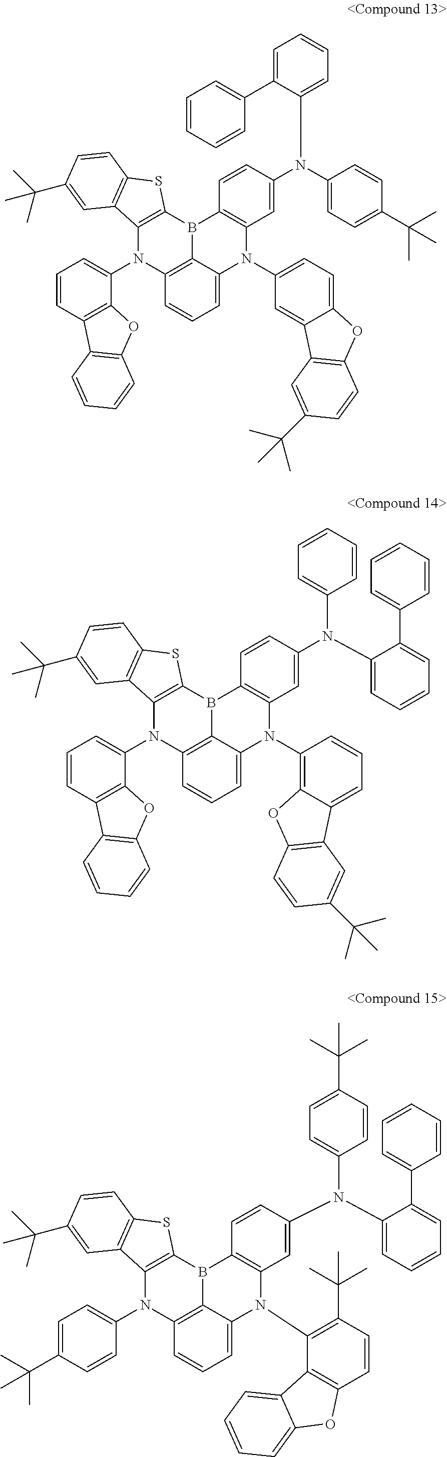 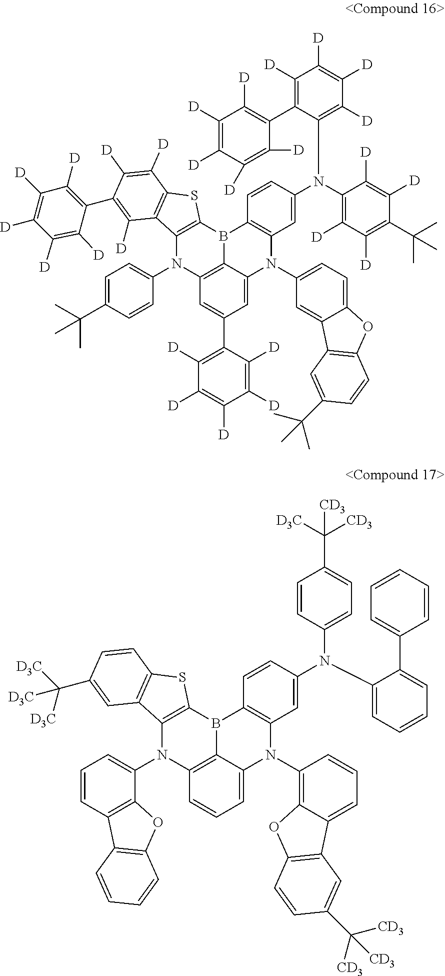 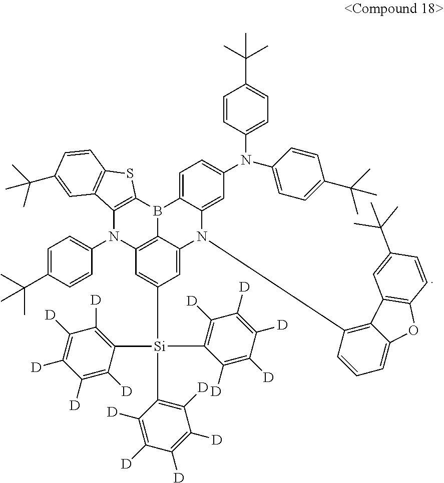 [SMILES: [2H]c1c([2H])c([2H])c([Si](c2cc3c4c(c2)N(c2cccc5oc6ccc(C(C)(C)C)cc6c25)c2cc(N(c5ccc(C(C)(C)C)cc5)c5ccc(C(C)(C)C)cc5)ccc2B4c2sc4ccc(C(C)(C)C)cc4c2N3c2ccc(C(C)(C)C)cc2)(c2c([2H])c([2H])c([2H])c([2H])c2[2H])c2c([2H])c([2H])c([2H])c([2H])c2[2H])c([2H])c1[2H]]
